(19) United States
(12) Patent Application Publication
(10) Pub. No.: US 2021/0233951 A1
(43) Pub. Date: Jul. 29, 2021

(54) SOLID-STATE IMAGING DEVICE AND METHOD OF MANUFACTURING SOLID-STATE IMAGING DEVICE

(71) Applicant: SONY SEMICONDUCTOR SOLUTIONS CORPORATION, Kanagawa (JP)

(72) Inventor: Yoichi OOTSUKA, Kanagawa (JP)

(73) Assignee: SONY SEMICONDUCTOR SOLUTIONS CORPORATION, Kanagawa (JP)

(21) Appl. No.: 17/053,858

(22) PCT Filed: Apr. 19, 2019
(86) PCT No.: PCT/JP2019/016784

§ 371 Date: Nov. 9, 2020

(30) Foreign Application Priority Data
May 16, 2018 (JP) 2018-094227
Sep. 20, 2018 (JP) 2018-175743

(51) Int. Cl. H01L 27/146; H04N 5/3745

(52) U.S. Cl. CPC H01L 27/14627; H01L 27/14621; H01L 27/14623; H01L 27/14685; H04N 5/3745; H01L 27/14636; H01L 27/14629; H01L 27/14645; H01L 27/14612

(57) ABSTRACT

A solid-state imaging device including: a plurality of pixels; and microlenses. Each of the pixels includes a photoelectric converter. The plurality of pixels is disposed along a first direction and a second direction. The microlenses are provided for respective pixels on light incident sides of the photoelectric converters. The microlenses include lens sections and an inorganic film. The lens sections each have a lens shape and are in contact with each other between the pixels adjacent in the first direction and the second direction. The inorganic film covers the lens sections. The microlenses each include first concave portions between the pixels adjacent in the first direction and the second direction, and second concave portions provided between the pixels adjacent in a third direction. The second concave portions are closer to the photoelectric converter than the first concave portions.

### TECHNICAL FIELD

The present technology relates to a solid-state imaging device including a microlens and a method of manufacturing the solid-state imaging device.

### BACKGROUND ART

As solid-state imaging devices applicable to solid-state imaging apparatuses such as digital cameras and video cameras, CCD (Charge Coupled Device), CMOS (Complementary Metal Oxide Semiconductor), and the like have been developed.

A solid-state imaging device includes, for example, a photoelectric converter provided to each pixel and a color filter provided on the light incidence side of the photoelectric converter and having a lens function (see, for example, PTL 1)

### CITTION LIST

### Patent Literature

PTL 1: Japanese Unexamined Patent Application Publication No. 2012-186363

### SUMMARY OF THE INVENTION

It is desired that such a solid-state imaging device increase the sensitivity.

It is thus desirable to provide a solid-state imaging device that allows the sensitivity to be increased.

A solid-state imaging device according to an embodiment of the present disclosure includes: a plurality of pixels; and microlenses. The plurality of pixels each includes a photoelectric converter. The plurality of pixels is disposed along a first direction and a second direction. The second direction intersects the first direction. The microlenses are provided to the respective pixels on light incidence sides of the photoelectric converters. The microlenses include lens sections and an inorganic film. The lens sections each have a lens shape and are in contact with each other between the pixels adjacent in the first direction and the second direction. The inorganic film covers the lens sections. The microlenses each include first concave portions provided between the pixels adjacent in the first direction and the second direction, and second concave portions provided between the pixels adjacent in a third direction. The second concave portions are disposed at positions closer to the photoelectric converter than the first concave portions. The third direction intersects the first direction and the second direction.

The solid-state imaging device according to the embodiment of the present disclosure has the lens sections in contact with each other between the pixels adjacent in the first direction and the second direction. This reduces pieces of light incident on the photoelectric converters without passing through the lens sections. The lens sections are provided to the respective pixels.

A method of manufacturing a solid-state imaging device according to an embodiment of the present disclosure includes: forming a plurality of pixels each including a photoelectric converter and being disposed along a first direction and a second direction intersecting the first direction; forming first lens sections side by side in the respective pixels on light incidence sides of the photoelectric converters in the third direction; forming second lens sections in the pixels different from the pixels in which the first lens sections are formed; forming an inorganic film covering the first lens sections and the second lens sections; and causing each of the first lens sections to have greater size in the first direction and the second direction than size of each of the pixels in the first direction and the second direction in forming the first lens sections. The first lens sections each have a lens shape.

The method of manufacturing the solid-state imaging device according to the embodiment of the present disclosure causes each of the first lens sections to have greater size in the first direction and the second direction than size of each of the pixels in the first direction and the second direction in forming the first lens sections. This easily forms the lens sections that are in contact with each other between the pixels adjacent in the first direction and the second direction. That is, it is possible to easily manufacture the solid-state imaging device according to the above-described embodiment of the present disclosure.

### BRIEF DESCRIPTION OF DRAWING

FIG. 1 is a block diagram illustrating an example of a functional configuration of an imaging device according to a first embodiment of the present disclosure.

FIG. 2 is a diagram illustrating an example of a circuit configuration of a pixel P illustrated in FIG. 1.

FIG. 3A is a planar schematic diagram illustrating a configuration of a pixel array unit illustrated in FIG. 1.

FIG. 3B is an enlarged schematic diagram illustrating a corner portion illustrated in FIG. 3A.

FIG 4 is a schematic diagram illustrating a cross-sectional configuration taken along an a-a′ line illustrated in FIG. 3A in (A) and a cross-sectional configuration taken along a b-b′ line illustrated in FIG. 3A in (B).

FIG. 5 is a cross-sectional schematic diagram illustrating another example of a configuration of a color filter section illustrating in (A) of FIG. 4.

FIG. 6 is a schematic diagram illustrating another example (1) of the cross-sectional configuration taken along the a-a′ line illustrated in FIG. 3A in (A) and another example (1) of the cross-sectional configuration taken along the b-b′ line illustrated in FIG. 3A in (B).

FIG. 7 is a planar schematic diagram illustrating a configuration of a light-shielding film illustrated in (A) and (B) of FIG. 4.

FIG. 8 is a schematic diagram illustrating another example (2) of the cross-sectional configuration taken along the a-a′ line illustrated in FIG. 3A in (A) and another example (2) of the cross-sectional configuration taken along the b-b′ line illustrated in FIG. 3A in (B).

FIG. 9 is a cross-sectional schematic diagram illustrating a configuration of a phase difference detection pixel illustrated in FIG. 1.

FIG. 10A is a schematic diagram illustrating an example of a planar configuration of the light-shielding film illustrated in FIG. 9.

FIG. 10B is a schematic diagram illustrating another example of the planar configuration of the light-shielding film illustrated in FIG. 9.

FIG. 11 is a schematic diagram illustrating a planar configuration of a color microlens illustrated in FIG. 3A.

FIG. 12A is a cross-sectional schematic diagram illustrating a step of steps of manufacturing the color microlens illustrated in FIG. 11.

FIG. 12B is a cross-sectional schematic diagram illustrating a step subsequent to FIG. 12A.

FIG. 12C is a cross-sectional schematic diagram illustrating a step subsequent to FIG. 12B.

FIG. 13A is a cross-sectional schematic diagram illustrating another example of the step subsequent to FIG. 12B.

FIG. 13B is a cross-sectional schematic diagram illustrating a step subsequent to FIG. 13A.

FIG. 14A is a cross-sectional schematic diagram illustrating a step subsequent to FIG. 12C.

FIG. 14B is a cross-sectional schematic diagram illustrating a step subsequent to FIG. 14A.

FIG. 14C is a cross-sectional schematic diagram illustrating a step subsequent to FIG. 14B.

FIG. 14D is a cross-sectional schematic diagram illustrating a step subsequent to FIG. 14C.

FIG. 14E is a cross-sectional schematic diagram illustrating a step subsequent to FIG. 14D.

FIG. 15A is a cross-sectional schematic diagram illustrating another example of the step subsequent to FIG. 14B.

FIG. 15B is a cross-sectional schematic diagram illustrating a step subsequent to FIG. 15A.

FIG. 15C is a cross-sectional schematic diagram illustrating a step subsequent to FIG. 15B.

FIG. 15D is a cross-sectional schematic diagram illustrating a step subsequent to FIG. 15C.

FIG. 16A is a cross-sectional schematic diagram illustrating another example of the step subsequent to FIG. 12C.

FIG. 16B is a cross-sectional schematic diagram illustrating a step subsequent to FIG. 16A.

FIG. 16C is a cross-sectional schematic diagram illustrating a step subsequent to FIG. 16B.

FIG. 16D is a cross-sectional schematic diagram illustrating a step subsequent to FIG. 16C.

FIG. 17A is a cross-sectional schematic diagram illustrating a step subsequent to FIG. 16D.

FIG. 17B is a cross-sectional schematic diagram illustrating a step subsequent to FIG. 17A.

FIG. 17C is a cross-sectional schematic diagram illustrating a step subsequent to FIG. 17B.

FIG. 17D is a cross-sectional schematic diagram illustrating a step subsequent to FIG. 17C.

FIG. 18 is a diagram illustrating a relationship between line width of a mask and line width of a color filter section.

FIG. 19A is a schematic cross-sectional view of a configuration of the color filter section in a case where the line width of the mask illustrated in FIG. 18 is greater than 1.1

FIG. 19B is a schematic cross-sectional view of a configuration of the color filter section in a case where the line width of the mask illustrated in FIG. 18 is less than or equal to 1.1 μm.

FIG. 20 is a diagram illustrating a spectral characteristic of the color filter section.

FIG. 21 is a diagram (1) respectively illustrating relationships between a radius of curvature of the color microlens and a focal point in an opposite side direction of a pixel and in a diagonal direction of the pixel in (A) and (B).

FIG. 22 is a diagram (2) respectively illustrating relationships between a radius of curvature of the color microlens and a focal point in an opposite side direction of a pixel and in a diagonal direction of the pixel in (A) and (B),

FIG. 23 is a cross-sectional schematic diagram illustrating a relationship between a structure and radius of curvature of the color microlens illustrated in FIG. 22.

FIG. 24 is a cross-sectional schematic diagram illustrating a configuration of an imaging device according to a modification example 1 in each of (A) and (B).

FIG. 25 is a cross-sectional schematic diagram illustrating a configuration of an imaging device according to a modification example 2 in each of (A) and (B).

FIG. 26 is a cross-sectional schematic diagram respectively illustrating another example of the imaging device illustrated in (A) and (B) of FIG. 25 in (A) and (B).

FIG. 27 is a planar schematic diagram illustrating a configuration of an imaging device according to a modification example 3.

FIG. 28 is a schematic diagram illustrating a cross-sectional configuration taken along a g-g′ line illustrated in FIG. 27 in (A) and a cross-sectional configuration taken along an h-h′ line illustrated in FIG. 27 in (B).

FIG. 29 is a planar schematic diagram illustrating a configuration of an imaging device according to a modification example 4.

FIG. 30 is a schematic diagram illustrating a cross-sectional configuration taken along an a-a′ line illustrated in FIG. 29 in (A) and a cross-sectional configuration taken along a b-b′ line illustrated in FIG. 29 in (B).

FIG. 31 is a planar schematic diagram illustrating a configuration of a light-shielding film illustrated in (A) and (B) of FIG. 30,

FIG. 32 is a cross-sectional schematic diagram illustrating a configuration of an imaging device according to a modification example 5 in each of (A) and (B).

FIG. 33 is a cross-sectional schematic diagram illustrating a configuration of an imaging device according to a modification example 6.

FIG. 34 is a cross-sectional schematic diagram illustrating a configuration of an imaging device according to a modification example 7.

FIG. 35 is a planar schematic diagram illustrating a configuration of a main unit of an imaging device according to a second embodiment of the present disclosure.

FIG. 36 is a schematic diagram illustrating a cross-sectional configuration taken along an a-a′ line illustrated in FIG. 35 in (A) and a cross-sectional configuration taken along a b-b′ line illustrated in FIG. 35 in (B).

FIG. 37 is a planar schematic diagram illustrating a step of steps of manufacturing a first lens section and second lens section illustrated in (A) and (B) of FIG. 36.

FIG. 38A is a schematic diagram illustrating a cross-sectional configuration along an a-a line in FIG. 37.

FIG. 38B is a schematic diagram illustrating a cross-sectional configuration along a b-b′ line in FIG. 37.

FIG. 39 is a planar schematic diagram illustrating a step subsequent to FIG. 37.

FIG. 40A is a schematic diagram illustrating a cross-sectional configuration along an a-a line in FIG. 39.

FIG. 40B is a schematic diagram illustrating a cross-sectional configuration along a b-b′ line in FIG. 39.

FIG. 41 is a planar schematic diagram illustrating a step subsequent to FIG. 39.

FIG. 42A is a schematic diagram illustrating a cross-sectional configuration along an a-a line in FIG. 41.

FIG. 42B is a schematic diagram illustrating a cross-sectional configuration along a b-b′ line in FIG. 41.

FIG. 43 is a planar schematic diagram illustrating a step subsequent to FIG. 41.

FIG. 44A is a schematic diagram illustrating a cross-sectional configuration along an a-a line in FIG. 43.

FIG. 44B is a schematic diagram illustrating a cross-sectional configuration along a b-b′ line in FIG. 43.

FIG. 45 is a planar schematic diagram illustrating another example a step of manufacturing the first lens section and second lens section illustrated in (A) and (B) of FIG. 36.

FIG. 46A is a schematic diagram illustrating a cross-sectional configuration along an a-a′ line in FIG. 45,

FIG. 46B is a schematic diagram illustrating a cross-sectional configuration along a b-b′ line in FIG. 45.

FIG. 47 is a planar schematic diagram illustrating a step subsequent to FIG. 45.

FIG. 48A is a schematic diagram illustrating a cross-sectional configuration along an a-a′ line in FIG. 47.

FIG. 48B is a schematic diagram illustrating a cross-sectional configuration along a b-b′ line in FIG. 47.

FIG. 49 is a planar schematic diagram illustrating a step subsequent to FIG. 47.

FIG. 50A is a schematic diagram illustrating a cross-sectional configuration along an a-a′ line in FIG. 49.

FIG. 50B is a schematic diagram illustrating a cross-sectional configuration along a b-b′ line in FIG. 49.

FIG. 51 is a planar schematic diagram illustrating a step subsequent to FIG. 49.

FIG. 52A is a schematic diagram illustrating a cross-sectional configuration along an a-a′ line in FIG. 51.

FIG. 52B is a schematic diagram illustrating a cross-sectional configuration along a b-b′ line in FIG. 51.

FIG. 53 is a planar schematic diagram illustrating a step subsequent to FIG. 51.

FIG. 54A is a schematic diagram illustrating a cross-sectional configuration along an a-a′ line in FIG. 53.

FIG. 54B is a schematic diagram illustrating a cross-sectional configuration along a b-b′ line in FIG. 53.

FIG. 55A is a planar schematic diagram illustrating a method of manufacturing a microlens by using a resist pattern that fits into a pixel.

FIG. 55B is a planar schematic diagram illustrating a step subsequent to FIG. 55A.

FIG. 55C is a planar schematic diagram illustrating a step subsequent to FIG. 55B.

FIG. 55D is an enlarged planar schematic diagram illustrating a portion illustrated in FIG. 55C.

FIG. 56 is a diagram illustrating an example of a relationship between a radius of curvature of the microlens illustrated in FIG. 55C and size of a pixel.

FIG. 57 is a cross-sectional schematic diagram illustrating a configuration of an imaging device according to a modification example 8.

FIG. 58 is a cross-sectional schematic diagram illustrating a configuration of a phase difference detection pixel of an imaging device according to a modification example 9.

FIG. 59 is a functional block diagram illustrating an example of an imaging apparatus (electronic apparatus) including the imaging device illustrated in FIG. 1 or the like.

FIG. 60 is a block diagram depicting an example of a schematic configuration of an in-vivo information acquisition system.

FIG. 61 is a view depicting an example of a schematic configuration of an endoscopic surgery system.

FIG. 62 is a block diagram depicting an example of a functional configuration of a camera head and a camera control unit (CCU).

FIG. 63 is a block diagram depicting an example of schematic configuration of a vehicle control system.

FIG. 64 is a diagram of assistance in explaining an example of installation positions of an outside-vehicle information detecting section and an imaging section.

### MODES FOR CARRYING OUT THE INVENTION

The following describes an embodiment of the present technology in detail with reference to the drawings, it is to be noted that description is given in the following order.
1. First Embodiment (example of solid-state imaging device in which color filter sections adjacent in opposite side direction of pixels are in contact with each other)
2. Modification Example 1 (example in which color filter sections between pixels adjacent in third direction are linked)
3. Modification Example 2 (example in which there is waveguide structure between adjacent pixels)
4. Modification Example 3 (example in which color microlenses have radii of curvature different between red, blue, and green)
5. Modification Example 4 (example in which color microlens has circular planar shape)
6. Modification Example 5 (example in which red or blue color filter section is formed before green color filter section)
7. Modification Example 6 (example of application to front-illuminated imaging device)
8. Modification Example 7 (example of application to WCSP (Wafer level Chip Size Package))
9. Second Embodiment (example of solid-state imaging device in which lens sections adjacent in opposite side direction of pixels are in contact with each other)
10. Modification Example 8 (example in which microlenses have radii of curvature different between red pixel, blue pixel, and green pixel)
11. Modification Example 9 (example in which phase difference detection pixel includes two photodiodes)
12. Other Modification Examples
13. Applied Example (Example of Electronic Apparatus)
14. Application Example

### First Embodiment

### (Overall Configuration of Imaging Device 10)

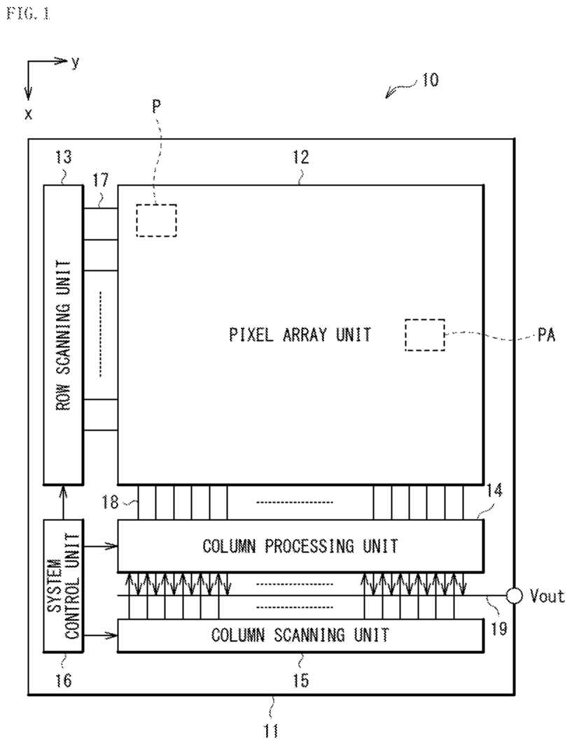

FIG. 1 is a block diagram illustrating an example of the functional configuration of a solid-state imaging device (imaging device 10) according to a first embodiment of the present disclosure. This imaging device 10 is, for example, an amplified solid-state imaging device such as a CMOS image sensor. The imaging device 10 may be another amplified solid-state imaging device. Alternatively, the imaging device 10 may he a solid-state imaging device such as CCD that transfers an electric charge.

The imaging device 10 includes a semiconductor substrate 11 provided with a pixel array unit 12 and a peripheral circuit portion. The pixel array unit 12 is provided, for example, in the middle portion of the semiconductor substrate 11. The peripheral circuit portion is provided outside the pixel array unit 12. The peripheral circuit portion includes, for example, a row scanning unit 13, a column processing unit 14, a column scanning unit 15, and a system control unit 16.

In the pixel array unit 12, unit pixels (pixels P) are two-dimensionally disposed in a matrix. The unit pixels (pixels P) each include a photoelectric converter that generates optical charges having the amount of electric charges corresponding to the amount of incident light and accumulates the optical charges inside. In other words, the plurality of pixels P is disposed along the X direction (first direction) and Y direction (second direction) of FIG. 1. A “unit pixel” here is an imaging pixel for obtaining an imaging signal. A specific circuit configuration of each pixel P (imaging pixel) is described below. In the pixel array unit 12, for example, phase difference detection pixels (phase difference detection pixels PA) are disposed along with the pixels P These phase difference detection pixels PA are each for obtaining a phase difference detection signal, This phase difference detection signal allows the imaging device 10 to achieve pupil division phase difference detection. The phase difference detection signal is a signal indicating a deviation direction (defocus direction) and a deviation amount (defocus amount) from a focal point. The pixel array unit 12 is provided, for example, with the plurality of phase difference detection pixels PA. These phase difference detection pixels PA are disposed to intersect each other, for example, in the left-right and up-down directions.

In the pixel array unit 12, a pixel drive line 17 is disposed for each pixel row of the matrix pixel arrangement along the row direction (arrangement direction of the pixels in the pixel row). A vertical signal line 18 is disposed for each pixel column along the column direction (arrangement direction of the pixels in the pixel column). The pixel drive line 17 transmits drive signals for driving pixels. The drive signals are outputted from the row scanning unit 13 row by row. FIG. 1 illustrates one wiring line for the pixel drive line 17, but the number of pixel drive lines 17 is not limited to one. The pixel drive line 17 has one of the ends coupled to the output end corresponding to each row of the row scanning unit 13.

The row scanning unit 13 includes a shift register, an address decoder, and the like. The row scanning unit 13 drives the respective pixels of the pixel array unit 12, for example, row by row. Here, a specific component of the row scanning unit 13 is not illustrated, but generally includes two scanning systems: a read scanning system; and a sweep scanning system.

To read signals from the unit pixels, the read scanning system sequentially selects and scans the unit pixels of the pixel array unit 12 row by row. The signals read from the unit pixels are analog signals. The sweep scanning system performs sweep scanning on a read row on which read scanning is performed by the read scanning system, the time of the shutter speed earlier than the read scanning.

This sweep scanning by the sweep scanning system sweeps out unnecessary electric charges from the photoelectric conversion sections of the unit pixels of the read row, thereby resetting the photoelectric conversion sections. This sweeping (resetting) the unnecessary charges by the sweep scanning system causes a so-called electronic shutter operation to be performed. Here, the electronic shutter operation is an operation of discarding the optical charges of the photoelectric conversion sections, and newly beginning exposure (beginning to accumulate optical charges).

The signals read through a read operation performed by the read scanning system correspond to the amount of light coming after the immediately previous read operation or electronic shutter operation. The period from the read timing by the immediately previous read operation or the sweep timing by the electronic shutter operation to the read timing. by the read operation performed this time then serves as the accumulation period (exposure period) of optical charges in a unit pixel.

A signal outputted from each of the unit pixels of the pixel rows selected and scanned by the row scanning unit 13 is supplied to the column processing unit 14 through each of the vertical signal lines 18. For the respective pixel columns of the pixel array unit 12, the column processing unit 14 performs predetermined signal processing on the signals outputted from the respective pixels of a selected row through the vertical signal lines 18 and temporarily retains the pixel signals subjected to the signal processing.

Specifically, upon receiving a signal of a unit pixel, the column processing unit 14 performs signal processing on that signal such as noise removal by CDS (Correlated Double Sampling), signal amplification, and AD (Analog-Digital) conversion, for example. The noise removal process causes fixed pattern noise specific to a pixel to be removed such as reset noise and a threshold variation of an amplification transistor. It is to be noted that the signal processing exemplified here is merely an example. The signal processing is not limited thereto.

The column scanning unit 15 includes a shift register, an address decoder, and the like. The column scanning unit 15 performs scanning of sequentially selecting unit circuits corresponding to the pixel columns of the column processing unit 14. The selection and scanning by the column scanning unit 15 cause the pixel signals subjected to the signal processing in the respective unit circuits of the column processing unit 14 to he sequentially outputted to a horizontal bus 19 and transmitted to the outside of the semiconductor substrate 11 through the horizontal bus 19.

The system control unit 16 receives a clock provided from the outside of the semiconductor substrate 11, data for issuing an instruction about an operation mode, or the like. In addition, the system control unit 16 outputs data such as internal information of the imaging device 10. Further, the system control unit 16 includes a timing generator that generates a variety of timing signals. The system control unit 16 controls the driving of the peripheral circuit portion such as the row scanning unit 13, the column processing unit 14, and the column scanning unit 15 on the basis of the variety of timing signals generated by the timing generator.

### (Circuit Configuration of Pixel P)

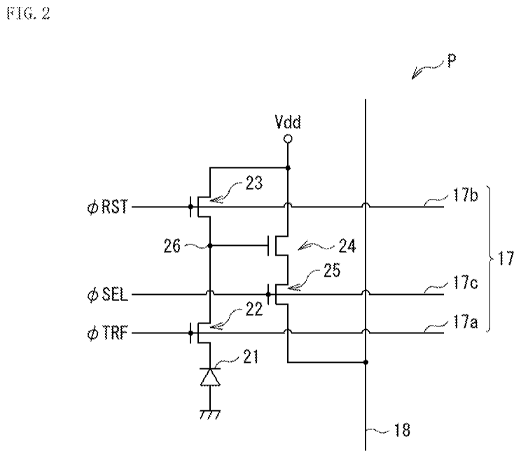

FIG. 2 is a circuit diagram illustrating an example of the circuit configuration of each pixel P.

Each pixel P includes, for example, a photodiode 21 as a photoelectric converter. For example, a transfer transistor 22, a reset transistor 23, an amplification transistor 24, and a selection transistor 25 are coupled to the photodiode 21 provided to each pixel P.

For example, N channel MOS transistors are usable as the four transistors described above. The electrically conductive combination of the transfer transistor 22, the reset transistor 23, the amplification transistor 24, and the selection transistor 25 exemplified here is merely an example. The combination of these is not limitative.

In addition, the pixel P is provided with three drive wiring lines as the pixel drive lines 17. The three drive wiring lines include, for example, a transfer line 17a, a reset line 17b, and a selection line 17c. The three drive wiring lines are common to the respective pixels P in the same pixel row. The transfer line 17a, the reset line 17b, and the selection line 17c each have an end coupled to the output end of the row scanning unit 13 corresponding to each pixel row in units of pixel rows. The transfer line 17a, the reset line 17b, and the selection line 17c transmit a transfer pulse φTRF, a reset pulse φRST, and a selection pulse φSEL that are drive signals for driving the pixels P.

The photodiode 21 has the anode electrode coupled to the negative-side power supply (e.g., ground). The photodiode 21 photoelectrically converts the received light (incident light) to the optical charges having the amount of electric charges corresponding to the amount of light and accumulates those optical charges. The cathode electrode of the photodiode 21 is electrically coupled to the gate electrode of the amplification transistor 24 via the transfer transistor 22. The node electrically joined to the gate electrode of the amplification transistor 24 is referred to as FD (floating diffusion) section 26.

The transfer transistor 22 is coupled between the cathode electrode of the photodiode 21 and the FD section 26. The gate electrode of the transfer transistor 22 is provided with the transfer pulse φTRF whose high level (e.g., Vdd level) is active (referred to as High active below) via the transfer line 17a. This makes the transfer transistor 22 conductive and the optical charges resulting from the photoelectric conversion by the photodiode 21 are transferred to the FD section 26.

The reset transistor 23 has the drain electrode coupled to a pixel power supply Vdd and has the source electrode coupled to the FD section 26. The gate electrode of the reset transistor 23 is provided with the reset pulse φRST that is High active via the reset line 17b. This makes the reset transistor 23 conductive and the FD section 26 is reset by discarding the electric charges of the FD section 26 to the pixel power supply Vdd.

The amplification transistor 24 has the gate electrode coupled to the FD section 26 and has the drain electrode coupled to the pixel power supply Vdd. The amplification transistor 24 then outputs the electric potential of the FD section 26 that has been reset by the reset transistor 23 as a reset signal (reset level) Vrst. Further, the amplification transistor 24 outputs, as a light accumulation signal (signal level) Vsig, the electric potential of the FD section 26 after the transfer transistor 22 transfers a signal charge.

For example, the selection transistor 25 has the drain electrode coupled to the source electrode of the amplification transistor 24 and has the source electrode coupled to the vertical signal line 18. The gate electrode of the selection transistor 25 is provided with the selection pulse φSEL that is High active via the selection line 17c. This makes the selection transistor 25 conductive and a signal supplied from the amplification transistor 24 with the unit pixel P selected is outputted to the vertical signal line 18.

In the example illustrated in FIG. 2, a circuit configuration is adopted in which the selection transistor 25 is coupled between the source electrode of the amplification transistor 24 and the vertical signal line 18, but it is also possible to adopt a circuit configuration in which the selection transistor 25 is coupled between the pixel power supply Vdd and the drain electrode of the amplification transistor 24.

The circuit configuration of each pixel P is not limited to a pixel configuration in which the four transistors described above are included. For example, a pixel configuration may be adopted in which three transistors one of which serves as both the amplification transistor 24 and the selection transistor 25 are included and the pixel circuits thereof may each have any configuration. The phase difference detection pixel PA has, for example, a pixel circuit similar to that of the pixel P.

### (Specific Configuration of Pixel P)

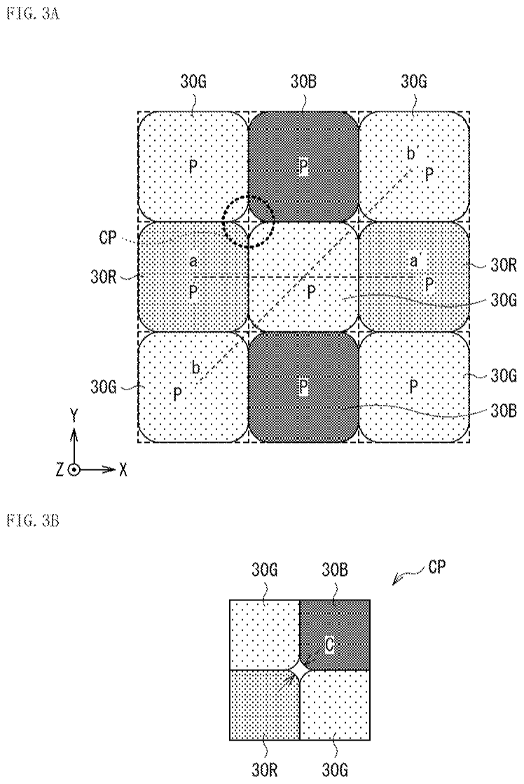

The following describes a specific configuration of the pixel P with reference to FIGS. 3A to 4. FIG. 3A more specifically illustrates the planar configuration of the pixel P and FIG. 3B is an enlarged view of a corner portion CP illustrated in FIG. 3A. (A) of FIG. 4 schematically illustrates the cross-sectional configuration taken along the a-a′ line illustrated in FIGS. 3A and (B) of FIG. 4 schematically illustrates the cross-sectional configuration taken along the b-b′ line illustrated in FIG. 3A.

This imaging device 10 is, for example, a back-illuminated imaging device. The imaging device 10 includes color microlenses 30R, 30G, and 30B on the surface of the semiconductor substrate 11 on the light incidence side and includes a wiring layer 50 on the surface of the semiconductor substrate 11 opposite to the surface on the light incidence side (FIG. 4). There are provided a light-shielding film 41 and a planarization film 42 between the color lensses 30R, 30G, and 30B and the semiconductor substrate 11.

The semiconductor substrate 11 includes, for example, silicon (Si). The photodiode 21 is provided to each pixel P near the surface of this semiconductor substrate 11 on the light incidence side. The photodiode 21 is, for example, a photodiode having a p-n junction and has a p-type impurity region and an n-type impurity region.

The wiring layer 50 opposed to the color microlenses 30R, 30G, and 30B with the semiconductor substrate 11 interposed therebetween includes, for example, a plurality of wiring lines and an interlayer insulating film. The wiring layer 50 is provided, for example, with a circuit for driving each pixel P. The back-illuminated imaging device 10 like this has a shorter distance between the color microlenses 30R, 30G, and 30B and the photodiodes 21 than that of a front-illuminated imaging device and it is thus possible to increase the sensitivity. In addition, the shading is also improved.

The color microlenses 30R, 30G, and 30B include color filter sections 31R, 31G, and 31B and an inorganic film 32. The color microlens 30R includes the color filter section 31R and the inorganic film 32. The color microlens 30G includes the color filter section 31(1 and the inorganic film 32. The color microlens 30B includes the color filter section 31B and the inorganic film 32. These color microlenses 30R, 30G, and 30B each have a light dispersing function as a color filter and a light condensing function as a microlens. Providing the color microlenses 30R, 30G, and 30B each having a light dispersing function and a light condensing function like this reduces the imaging device 10 in height as compared with an imaging device provided with color filters and microlenses separately. This makes it possible to increase the sensitivity characteristic. Here, the color filter sections 31R, 31G, and 31B each correspond to a specific example of a lens section of the present disclosure.

The color microlenses 30R, 30G, and 30B are disposed at the respective pixels P. Any of the color microlens 30R, color microlens 30G, and color microlens 30B is disposed at each pixel P (FIG. 3A). For example, the pixel P (red pixel) at which the color microlens 30R is disposed obtains the received-light data of light within the red wavelength range. The pixel P (green pixel) at which the color microlens 30G is disposed obtains the received-light data of light within the green wavelength range. The pixel P (blue pixel) at which the color microlens 30B is disposed obtains the received-light data of light within the blue wavelength range.

The planar shape of each pixel P is, for example, a quadrangle such as a square. The planar shape of each of the color microlenses 30R, 30G, and 30B is a quadrangle that has substantially the same size as the size of the pixel P. The sides of the pixels P are provided substantially in parallel with the arrangement directions (row direction and column direction) of the pixels P. It is preferable that each pixel P be a square having a side of 1.1 μm or less. As described below, this makes it easy to make the color filter sections 31R, 31G, and 31B that each have a lens shape. The color microlenses 30R, 30G, and 30B are provided substantially without chamfering the corner portions of the quadrangles. The corner portions of the pixels P are substantially covered by the color microlenses 30R, 30G, and 30B. It is preferable that gaps C between the adjacent color microlenses 30R, 30G, and 30B (color microlens 30R and color microlens 30B in FIG. 3B) have the wavelength (e.g., 400 nm) of light in the visible region or less in a diagonal direction (e.g., direction inclined by 45° to the X direction and Y direction in FIG. 3A or third direction) of the quadrangular pixels P in a plan (XY plane in FIG. 3A) view. The adjacent color microlenses 30R, 30G, and 30B are in contact with each other in a plan view in the opposite side directions (e.g., X direction and Y direction in FIG. 3A) of the quadrangular pixels P.

Each of the color filter sections 31R, 31G, and 31B each having a light dispersing function has a lens shape. Specifically, the color filter sections 31R, 31G, and 31B each have a convex curved surface on the side opposite to the semiconductor substrate 11 (FIG. 4). Each pixel P is provided with any of these color filter sections 31R, 31G, and 31B. These color filter sections 31R, 31G, and 31B are disposed, for example, in regular color arrangement such as Bayer arrangement. For example, the color filter section 31G are disposed side by side along the diagonal directions of the quadrangular pixels P. The adjacent color filter sections 31R, 31G, and 31B may partly overlap with each other between the adjacent pixels P. For example, the color filter section 31R (or the color filter section 31B) is provided on the color filter section 31G.

The planar shape of each of the color filter sections 31R, 31G, and 31B is, for example, a quadrangle that has substantially the same size as that of the planar shape of the pixel P (FIG. 3A). In the present embodiment, the adjacent color filter sections 31R, 31G, and 31B (color filter section 31G and color filter section 31R in (A) of FIG. 4) in the opposite side directions of the quadrangular pixels P overlap with each other at least partly in the thickness direction (e.g., Z direction in (A) of FIG. 4). That is, almost all the regions between the adjacent pixels P are provided with the color filter sections 31R, 31G, and 31B. This reduces pieces of light incident on the photodiodes 21 without passing through the color filter sections 31R, 31G, and 31B. This makes it possible to suppress a decrease in sensitivity and the generation of a color mixture between the adjacent pixels P caused by the pieces of light incident on the photodiodes 21 without passing through the color filter sections 31R, 31G, and 31B. For example, the light-shielding film 41 is provided between the adjacent color filter sections 31R, 31G, and 31B (between the color filter sections 31G in (B) of FIG. 4) in the diagonal directions of the quadrangular pixels P and the color filter sections 31R, 31G, and 31B are in contact with this light-shielding film 41.

The color filter sections 31R, 31G, and 31B each include, for example, a lithography component for forming the shape thereof and a pigment dispersion component for attaining the light dispersing function. The lithography component includes, for example, a binder resin, a polymerizable monomer, and a photo-radical generator. The pigment dispersion component includes, for example, a pigment, a pigment derivative, and a dispersion resin.

FIG. 5 illustrates another example of the cross-sectional configuration taken along the a-a′ line illustrated in FIG. 3A. In this way, the color filter section 31G (or the color filter sections 31R and 31B) may include a stopper film 33 on the surface. This stopper film 33 is used to form each of the color filter sections 31R, 31G, and 31B by dry etching as described below. The stopper film 33 is in contact with the inorganic film 32, In a case where the color filter sections 31R, 31G, and 31B each include the stopper film 33, the stopper films 33 of the color filter sections 31R, 31G, and 31B may be in contact with the color filter sections 31R, 31G, and 31B adjacent in the opposite side directions of the pixels P. The stopper film 33 includes, for example, a silicon oxynitride film (SiON), silicon oxide film (SiO), or the like having a thickness of about 5 nm to 200 nm.

The inorganic film 32 covering the color filter sections 31R, 31G, and 31B is provided, for example, as common to the color microlenses 30R, 30G, and 30B. This inorganic film 32 increases the effective area of the color filter sections 31R, 31G, and 31B. The inorganic film 32 is provided along the lens shape of each of the color filter sections 31R, 31G, and 31B. The inorganic film 32 includes, for example, a silicon oxynitride film, a silicon oxide film, a silicon oxycarbide film (SiOC), a silicon nitride film (SiN), or the like. The inorganic film 32 has, for example, a thickness of about 5 nm to 200 nm.

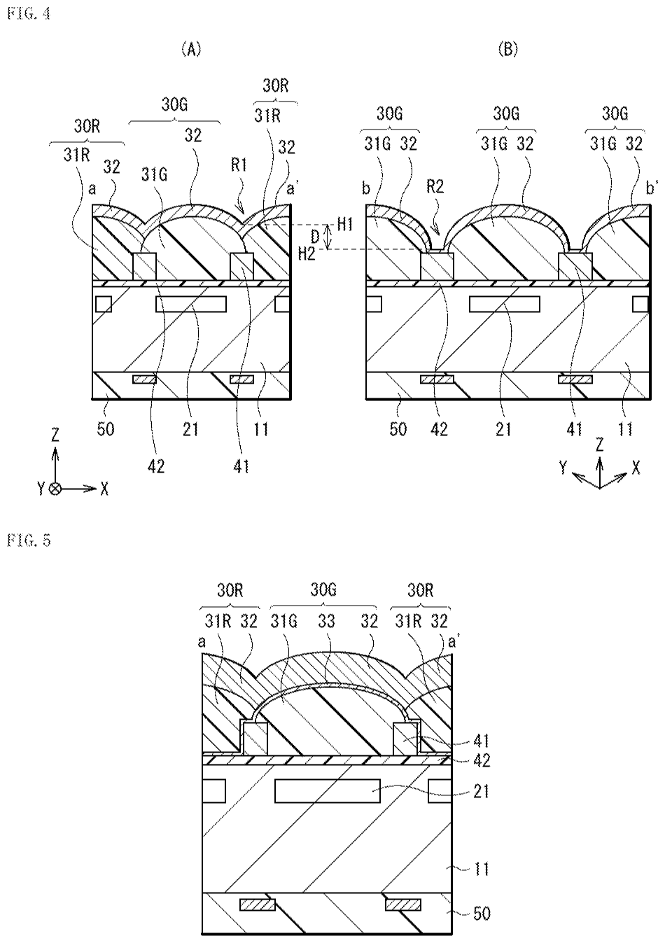

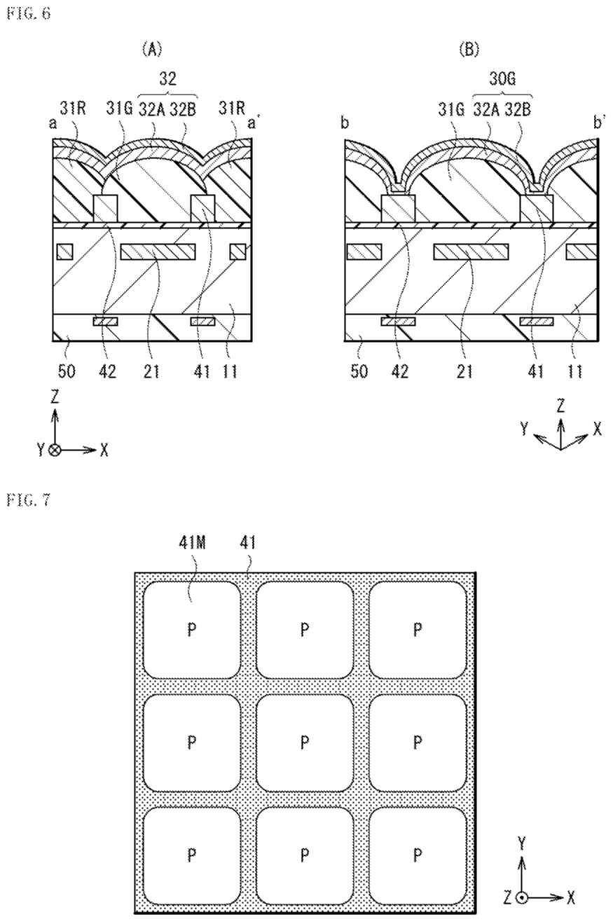

(A) of FIG. 6 illustrates another example of the cross-sectional configuration taken along the a-a′ line illustrated in FIG. 3A and (B) of FIG. 6 illustrates another example of the cross-sectional configuration taken along the b-b′ line illustrated in FIG. 3A. In this way, the inorganic film 32 may include a stacked film of a plurality of inorganic films (inorganic films 32A and 32B). For example, the inorganic film 32A and the inorganic film 32B are provided in this inorganic film 32 in this order from the color filter sections 31R, 31G, and 31B side, The inorganic film 32 may include a stacked film including three or more inorganic films.

The inorganic film 32 may have the function of an antireflection film. In a case where the inorganic film 32 is a single-layer film, the refractive index of the inorganic film 32 smaller than the refractive indices of the color filter sections 31R, 31G, and 31B allows the inorganic film 32 to function as an antireflection film. For example, a silicon oxide film (refractive index of about 1.46), a silicon ox carbide film (refractive index of about 1.40), or the like is usable as the inorganic film 32 like this. In a case where the inorganic film 32 is, for example, a stacked film including the inorganic films 32A and 32B, the refractive index of the inorganic film 32A larger than the refractive indices of the color filter sections 31R, 31G, and 31B and the refractive index of the inorganic film 32B smaller than the refractive indices of the color filter sections 31R, 31G, and 31B allow the inorganic film 32 to function as an antireflection film. For example, a silicon oxynitride film (refractive index of about 1.47 to 1.9), a silicon nitride film (refractive index of about 1.81 to 1.90), or the like is usable as the inorganic film 32A like this. For example, a silicon oxide film (refractive index of about 1.46), a silicon oxycarbide film (refractive index of about 1.40), or the like is usable as the inorganic film 32B.

The color microlenses 30R, 30G, and 30B including the color filter sections 31R, 31G, and 31B and the inorganic film 32 like these are provided with concave and convex portions along the lens shapes of the color filter sections 31R, 31G, and 31B ((A) and (B) of FIG. 4). The color microlenses 30R, 30G, and 30B are highest in the middle portions of the respective pixels P. The middle portions of the respective pixels P are provided with the convex portions of the color microlenses 30R, 30G, and 30B. The color microlenses 30R, 30G, and 30B are gradually lower from the middle portions of the respective pixels P to the outside (adjacent pixels P side). The concave portions of the color microlenses 30R, 30G, and 30B are provided between the adjacent pixels P.

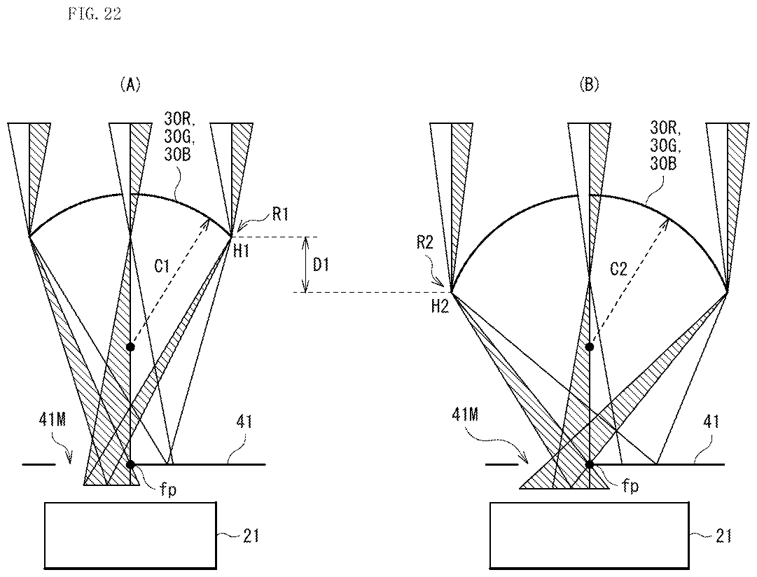

The color microlenses 30R, 30G, and 30B include first concave portions R1 between the color microlenses 30R, 30G, and 30B adjacent in the opposite side directions of the quadrangular pixels P (between the color microlens 30G and the color microlens 30R in (A) of FIG. 4). The color microlenses 30R, 30G, and 30B include second concave portions R2 between the color microlenses 30R, 30G, and 30B adjacent in the diagonal directions of the quadrangular pixels P (between the color microlenses 30G in (B) of FIG. 4), The position (position H1) of each of the first concave portions R1 in the height direction (e.g., Z direction in (A) of FIG. 4) and the position (position H2) of each of the second concave portions R2 in the height direction are defined, for example, by the inorganic film 32. Here, this position H2 of the second concave portion R2 is lower than the position H1 of the first concave portion R1. The position H2 of the second concave portion R2 is a position closer by distance D to the photodiode 21 than the position H1 of the first concave portion R1. Although the details are described below, this causes the radius of curvature (radius C2 of curvature in (B) of FIG. 22 below) of each of the color microlenses 30R, 30G, and 30B in the diagonal directions of the quadrangular pixels P to approximate to the radius of curvature (radius C1 of curvature in (A) of FIG. 22 below) of each of the color microlenses 30R, 30G, and 30B in the opposite side directions of the quadrangular pixels P, making it possible to increase the accuracy of pupil division phase difference AF (autofocus).

The light-shielding film 41 is provided between the color filter sections 31R, 31G, and 31B and the semiconductor substrate 11, for example, in contact with the color filter sections 31R, 31G, and 31B. This light-shielding film 41 suppresses a color mixture between the adjacent pixels P caused by oblique incident light, The light-shielding film 41 includes, for example, tungsten (W), titanium (Ti), aluminum (Al), copper (Cu), or the like. A resin material containing a black pigment such as black carbon or titanium black may be included in the light-shielding film 41.

FIG. 7 illustrates an example of the planar shape of the light-shielding film 41. The light-shielding film 41 has an opening 41M for each pixel P and the light-shielding film 41 is provided between the adjacent pixels P. The opening 41M has, for example, a quadrangular planar shape. The color filter sections 31R, 31G, and 31B are each embedded in this opening 41M of the light-shielding film 41. The ends of the respective color filter sections 31R, 31G, and 31B are provided on the light-shielding film 41 ((A) and (B) of FIG. 4). The inorganic film 32 is provided above the light-shielding film 41 in the diagonal directions of the quadrangular pixels P.

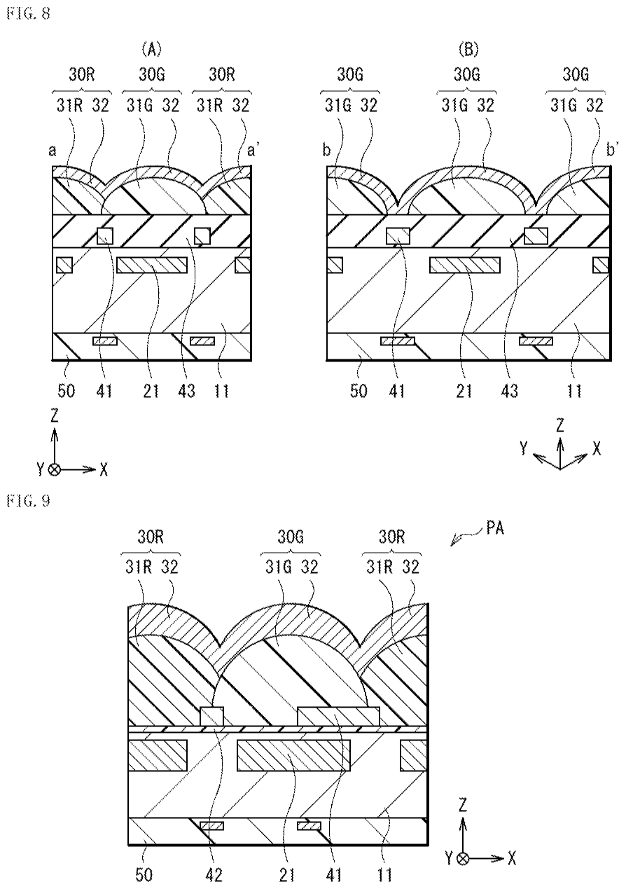

(A) of FIG. 8 illustrates another example of the cross-sectional configuration taken along the a-a′ line illustrated in FIG. 3A and (B) of FIG. 8 illustrates another example of the cross-sectional configuration taken along the b-b′ line illustrated in FIG. 3A. In this way, the light-shielding film 41 does not have to be in contact with the color microlenses 30R, 30G, and 30B. Fax example, there is provided an insulating film (insulating film 43) between the semiconductor substrate 11 and the color microlenses 30R, 30G, and 30B and the light-shielding film 41 may be covered with the insulating film 43, Each of the color microlenses 30R, 30G, and 30B (color filter sections 31R, 31G, and 31B) is then embedded in the opening 41M of the light-shielding film 41,

The planarization film 42 provided between the light-shielding film 41 and the semiconductor substrate 11 planarizes the surface of the semiconductor substrate 11 on the light incidence side. This planarization film 42 includes, for example, silicon nitride (SiN), silicon oxide (SiO), silicon oxynitride (SiON), or the like. The planarization film 42 may have a single-layer structure or a stacked structure.

### (Configuration of Phase Difference Detection Pixel PA)

FIG. 9 schematically illustrates the cross-sectional configuration of the phase difference detection pixel PA provided to the pixel array unit 12 (FIG. 1) along with the pixel P. As with the pixel P, the phase difference detection pixel PA includes the planarization film 42, the light-shielding film 41, and the color microlenses 30R, 30G, and 30B on the surface of the semiconductor substrate 11 on the light incidence side in this order. The phase difference detection pixel PA includes the wiring layer 50 on the surface of the semiconductor substrate 11 opposite to the light incidence side. The phase difference detection pixel PA includes the photodiode 21 provided to the semiconductor substrate 11. The light-shielding film 41 is provided to the phase difference detection pixel PA to cover the photodiode 21.

(A) and (B) of FIG. 10 each illustrate an example of the planar shape of the light-shielding film 41 provided to the phase difference detection pixel PA. The opening 41M of the light-shielding film 41 of the phase difference detection pixel PA is smaller than the opening 41M provided to the pixel P. The opening 41M is disposed closer to one or the other of the row direction or column direction (X direction in (A) and (B) of FIG. 10). For example, the opening 41M provided to the phase difference detection pixel PA is substantially half the size of the opening 41M provided to the pixel P. This causes one or the other of the pieces of light subjected to pupil division to pass through the opening 41M in the phase difference detection pixel PA and a phase difference is detected. The phase difference detection pixels PA including the light-shielding film 41 illustrated in (A) and (B) of FIG. 10 are disposed, for example, along the X direction. The phase difference detection pixels PA each having the opening 41M disposed closer to one or the other of the sides of the Y direction along disposed along the Y direction.

### (Method of Manufacturing Imaging Device 10)

The imaging device 10 may be manufactured, for example, as follows.

The semiconductor substrate 11 including the photodiode 21 is first formed. A transistor (FIG. 2) or the like is then formed on the semiconductor substrate 11. Afterward, the wiring layer 50 is formed on one (surface opposite to the light incidence side) of the surfaces of the semiconductor substrate 11. Next, the planarization film 42 is formed on the other of the surfaces of the semiconductor substrate 11.

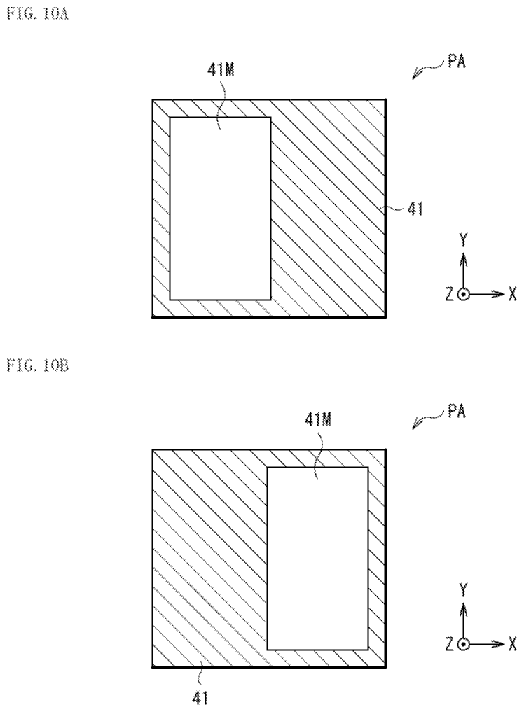

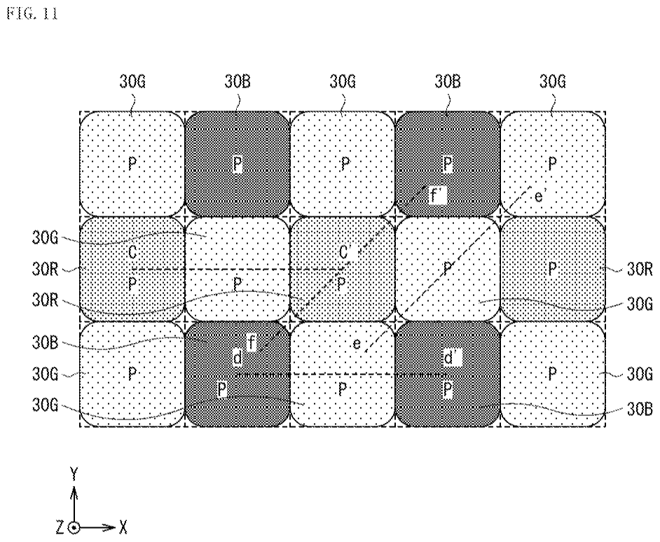

After the planarization film 42 is formed, the light-shielding film 41 and the color microlenses 30R, 30G, and 30B are formed in this order. FIG. 11 illustrates the planar configurations of the completed color microlenses 30R, 30G. and 30B. FIGS. 12A to 17D illustrate steps of forming the color microlenses 30R, 30G, and 30B as cross sections taken along the c-c′ line, d-d′ line, e-e′ line, and f-f′ line illustrated in FIG. 11. The following describes steps of forming the light-shielding film 41 and color microlenses 30R, 30G, and 30B with reference to these diagrams.

As illustrated in FIG. 12A, the light-shielding film 41 is first formed on the planarization film 42. The light-shielding film 41 is formed, for example, by forming a film of a light-shielding metal material on the planarization film 42 and then providing the opening 41M thereto.

Next, as illustrated in FIG. 12B, the light-shielding film 41 is coated with a color filter material 31GM. The color filter material 31GM is a material included in the color filter section 31G and includes, for example, a photopolymerizable negative photosensitive resin and a dye. For example, a pigment such as an organic pigment is used for the dye. The color filter material 31GM is prebaked, for example, after subjected to spin coating.

After the color filter material 31GM is prebaked, the color filter section 316 is formed as illustrated in FIG. 12C. The color filter section 31G is formed by exposing, developing, and prebaking the color filter material 31GM in this order. The exposure is performed, for example, by using a photomask for a negative resist and an i line. For example, puddle development using a TMAH (tetramethylammonium hydroxide) aqueous solution is used for the development. The concave portions of the color filter sections 316 formed in a diagonal direction (e-e′) of the pixels P are then formed to be lower than the concave portions formed in the opposite side directions (c-c′ and d-d′) of the pixels P. In this way, it is possible to form the color filter section 31G having a lens shape by using lithography.

It is preferable that the square pixel P have a side of 1.1 μm or less in a case where the color filter section 31G (or color filter sections 31R and 31B) having a lens shape are formed by using lithography. The following describes the reason for this.

FIG. 18 illustrates the relationship between the line width of a mask used for lithography and the line width of each of the color filter sections 31R, 31G, and 31B formed by this. The patterning characteristics by this lithography are examined by using an i line for exposure and setting 0.65 μm as the thickness of each of the color filter sections 31R, 31G, and 31B. This indicates that the line width of each of the color filter sections 31R, 31G, and 31B and the line width of a mask have linearity within the range within which the line width of the mask is greater than 1.1 μm and less than 1.5 μm. In contrast, in a case where the line width of the mask is less than or equal to 1.1 μm, the color filter sections 31R, 31G, and 31B are formed out of this linearity.

FIGS. 19A and 19B each schematically illustrate the cross-sectional configurations of the color filter sections 31R, 31G, and 31B formed by using lithography. FIG. 19A illustrates that the line width of a mask is greater than 1.1 μm and FIG. 19B illustrates that the line width of a mask is 1.1 μm or less. In this way, the color filter sections 31R., 31G, and 31B formed out of linearity with the line width of a mask each have a lens shape with a convex curved surface. Setting 1.1 μm or less as sides of the quadrangular pixels P thus makes it possible to form the color filter sections 31R, 31G, and 31B each having a lens shape by using simple lithography.

For example, if a mask has a line width of 0.5 μm or more, a general photoresist material makes it possible to form a pattern having linearity with the line width of the mask. The following describes why the area is narrower where the color filter sections 31R, 31G, and 31B having linearity with the line width of a mask in a case where the color filter sections 31R, 31G, and 31B are formed by using lithography.

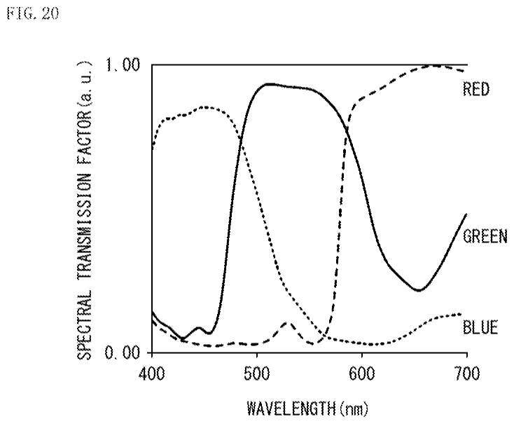

FIG. 20 illustrates the spectral transmission factors of the color filter sections 31R, 31G, and 31B. In this way, the color filter sections 31R, 31G, and 31B have the respective spectral characteristics specific thereto. These spectral characteristics are adjusted by the pigment dispersion components included in the color filter sections 31R, 31G, and 31B, These pigment dispersion components influence light used for exposure in lithography. For example, an i line has a spectral transmission factor of 0.3 a.u. or less for the color filter sections 31R, 31G, and 31B. For example, once a photoresist material absorbs the i line, the patterning characteristic is lowered. This lowered patterning characteristic stands out as the line width of a mask is smaller. In this way, the pigment dispersion components included in materials (e.g., color filter materials 31GM FIG. 12B) included in the color filter sections 31R, 31G, and 31B make it easier for the color filter sections 31R, 31G, and 31B to be out of linearity with the line width of the mask.

It is to be noted that, in a case where it is desired to improve linearity, the type or amount of radical generators included as a lithography component may be adjusted. Alternatively, the solubility of a polymerizable monomer, binder resin, or the like included as a lithography component may be adjusted. Examples of the adjustment of solubility include adjusting the amount of hydrophilic groups or carbon unsaturated bonds contained in a molecular structure.

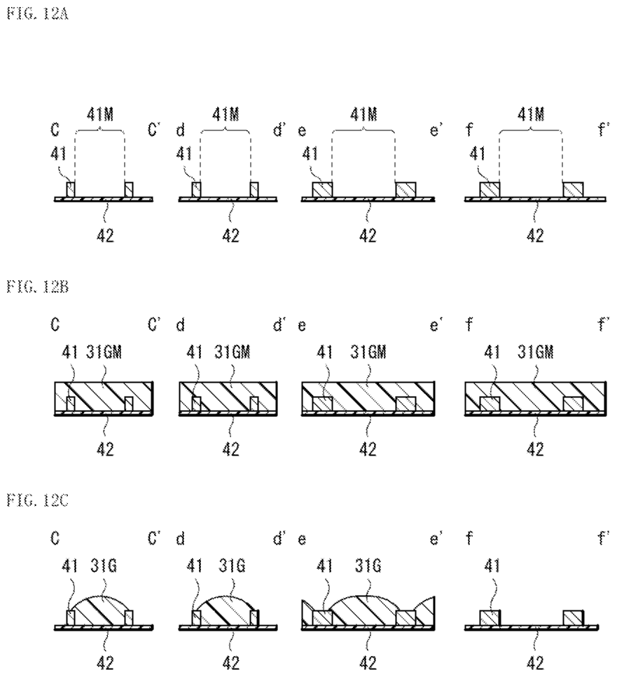

It is also possible to form the color filter section 31G by using dry etching (FIGS. 13A and 13B)

The light-shielding film 41 is first coated with the color filter material 31GM (FIG. 12B) and the color filter material 31GM is then subjected to curing treatment. The color filter material 31GM includes, for example, a thermosetting resin and a dye. The color filter material 31GM is baked as curing treatment, for example, after subjected to spin coating. The color filter material 31GM may include a photopolymerizable negative photosensitive resin instead of a thermosetting resin. For example, ultraviolet irradiation and baking are then performed in this order as the curing treatment.

After the color filter material 31GM is subjected to curing treatment, a resist pattern R having a predetermined shape is formed at the position corresponding to the green pixel P as illustrated in FIG. 13A. The resist pattern R is formed by first subjecting, for example, a photolytic positive photosensitive resin material to spin coating on the color filter material 31GM and then performing prebaking, exposure, post-exposure baking, development, and post-baking in this order. The exposure is performed, for example, by using a photomask for a positive resist and an i line. Instead of an i line, an excimer laser (e.g., KrF (krypton fluoride, ArF (argon fluoride), or the like) may be used. For example, puddle development using a TMAH (tetramethylammonium hydroxide) aqueous solution is used for the development.

After the resist pattern R is formed, the resist pattern R is transformed into a lens shape as illustrated in FIG. 13B. The resist pattern R is transformed, for example, by using a thermal melt flow method.

After the resist pattern R having a lens shape is formed, the resist pattern R is transferred to the color filter material 31GM, for example, by using dry etching. This forms the color filter section 31G (FIG. 12C).

Examples of apparatuses used for dry etching include a microwave plasma etching apparatus, a parallel plate RIE (Reactive Ion Etching) apparatus, a high-pressure narrow-gap plasma etching apparatus, an ECR (Electron Cyclotron Resonance) etching apparatus, a transformer coupled plasma etching apparatus, an inductively coupled plasma etching apparatus, a helicon wave plasma etching apparatus, and the like. It is also possible to use a high-density plasma etching apparatus other than those described above. For example, it is possible to use oxygen (O₂), carbon tetrafluoride (CE₄), chlorine (Cl₂), nitrogen (N₂), argon (Ar), and the like adjusted as appropriate for etching gas.

After the color filter section 31G is formed in this way by using lithography or dry etching, for example, the color filter section 31R and the color filter section 31B are formed in this order. It is possible to form each of the color filter section 31R and the color filter section 31B, for example, by using lithography or dry etching.

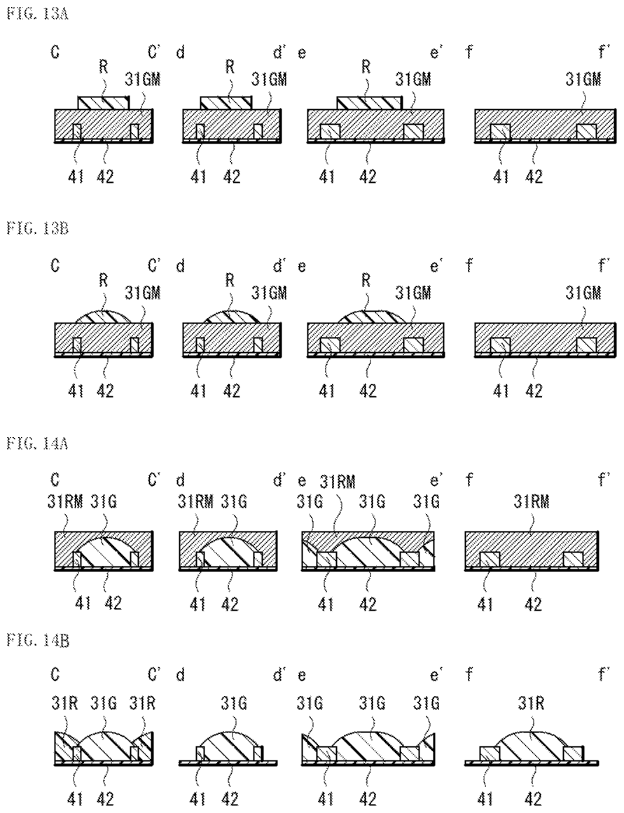

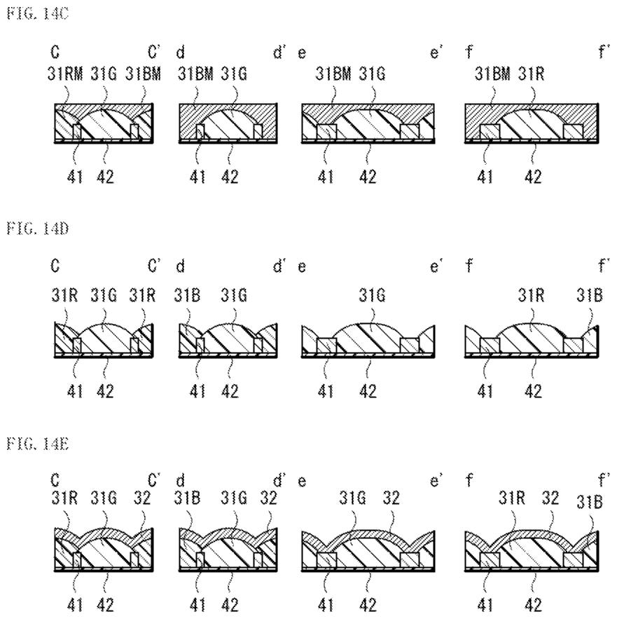

FIGS. 14A to 14D illustrate steps of forming the color filter section 31R and the color filter section 31B by using lithography.

As illustrated in FIG. 14A, the entire surface of the planarization film 42 is first coated with a color filter material 31RM to cause the color filter section 31G to be covered. The color filter material 31RM is a material included in the color filter section 31R and includes, for example, a photopolymerizable negative photosensitive resin and a dye. The color filter material 31RM is prebaked, for example, after subjected to spin coating.

After the color filter material 31RM is prebaked, the color filter section 31R is formed as illustrated in FIG. 14B. The color filter section 31R is formed by exposing, developing, and prebaking the color filter material 31RM in this order, The color filter sections 31R is then formed at least partly in contact with the adjacent color filter section 31G in an opposite side direction (c-c′) of the pixels P.

After the color filter section 31R is formed, the entire surface of the planarization film 42 is coated with a color filter material 31BM to cause the color filter sections 31G and 31R to be covered as illustrated in FIG. 14C. The color filter material 31BM is a material included in the color filter section 31B and includes, for example, a photopolymerizable negative photosensitive resin and a dye. The color filter material 31BM is prebaked, for example, after subjected to spin coating.

After the color filter material 31BM is prebaked, the color filter section 31B is formed as illustrated in FIG. 14D. The color filter section 31B is formed by exposing, developing, and prebaking the color filter material 31BM in this order. The color filter sections 31B is then formed at least partly in contact with the adjacent color filter section 31G in an opposite side direction (d-d′) of the pixels

After the color filter sections 31R, 31G, and 31B are formed, the inorganic film 32 is formed that covers the color filter sections 31R, 31G, and 31B as illustrated in FIG. 14E. This forms the color microlenses 30R, 30G, and 30B. Here, the color filter sections 31R, 31G, and 31B adjacent in the opposite side directions (c-c′ and d-d′) of the pixels P are provided in contact with each other. This reduces the time for forming the inorganic film 32 as compared with the separated. color filter sections 31R, 31G, and 31B. This makes it possible to reduce the manufacturing cost.

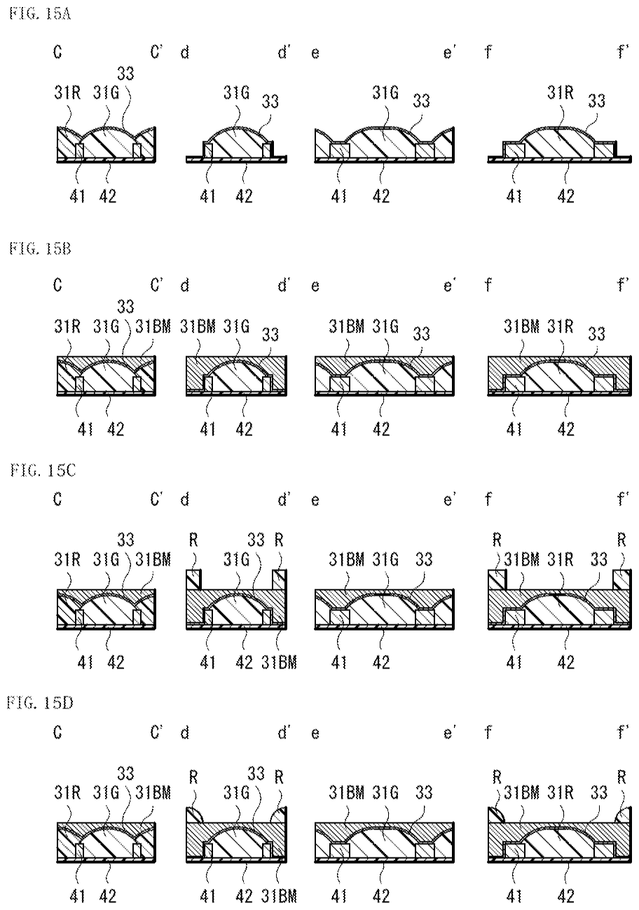

After the color filter section 31R is formed by using lithography (FIG. 14B), the color filter section 31B may be formed by using dry etching (FIGS. 15A to 15D).

After the color filter section 31R is formed (FIG. 14B), the stopper films 33 are formed that cover the color filter sections 31R and 31G as illustrated in FIG. 15A. This forms the stopper films 33 on the surfaces of the color filter sections 31R and 31G.

After the stopper films 33 are formed, the color filter material 31BM is applied and the color filter material 31BM is subsequently subjected to curing treatment as illustrated in FIG. 15B.

After the color filter material 31BM is subjected to curing treatment, the resist pattern R having a predetermined shape is formed at the position corresponding to the blue pixel P as illustrated in FIG. 15C.

After the resist pattern. R is formed, the resist pattern R is transformed into a lens shape as illustrated in FIG. 15D. Afterward, the resist pattern R is transferred to the color filter material 31GM, for example, by using dry etching. This forms the color filter section 31B (FIG. 14D). The color filter sections 31B is then formed at least partly in contact with the stopper film 33 of the adjacent color filter section 31G in an opposite side direction (d-d′) of the pixels P.

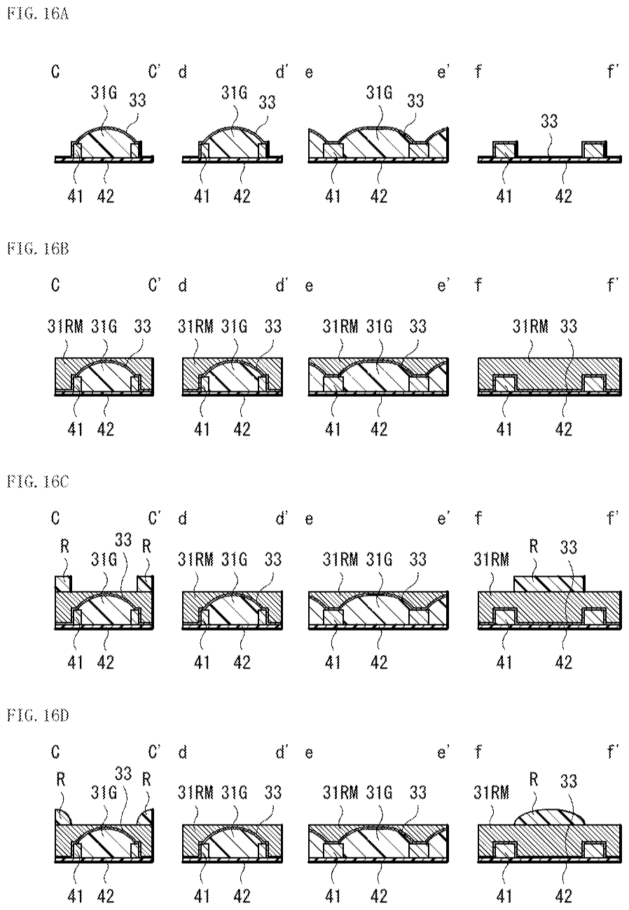

After the color filter section 31G is formed by using lithography or dry etching (FIG. 12C), the color filter section 31R may he formed by using dry etching (FIGS. 16A to 16D).

After the color filter section 31G is formed (FIG. 12C), the stopper film 33 is formed that covers the color filter section 31G as illustrated in FIG. 16A. This forms the stopper film 33 on the surface of the color filter section 31G.

After the stopper film 33 is formed, the color filter material 31RM is applied and the color filter material 31RM is subsequently subjected to curing treatment as illustrated in FIG. 16B.

After the color filter material 31RM is subjected to curing treatment, the resist pattern R having a predetermined shape is formed at the position corresponding to the red pixel P as illustrated in FIG. 16C.

After the resist pattern R is formed, the resist pattern R is transformed into a lens shape as illustrated in FIG. 16D. Afterward, the resist pattern R is transferred to the color filter material 31RM, for example, by using dry etching. This forms the color filter section 31R (FIG. 14B). The color filter sections 31R is then formed at least partly in contact with the stopper film 33 of the adjacent color filter section 31G in an opposite side direction (c-c′) of the pixels P.

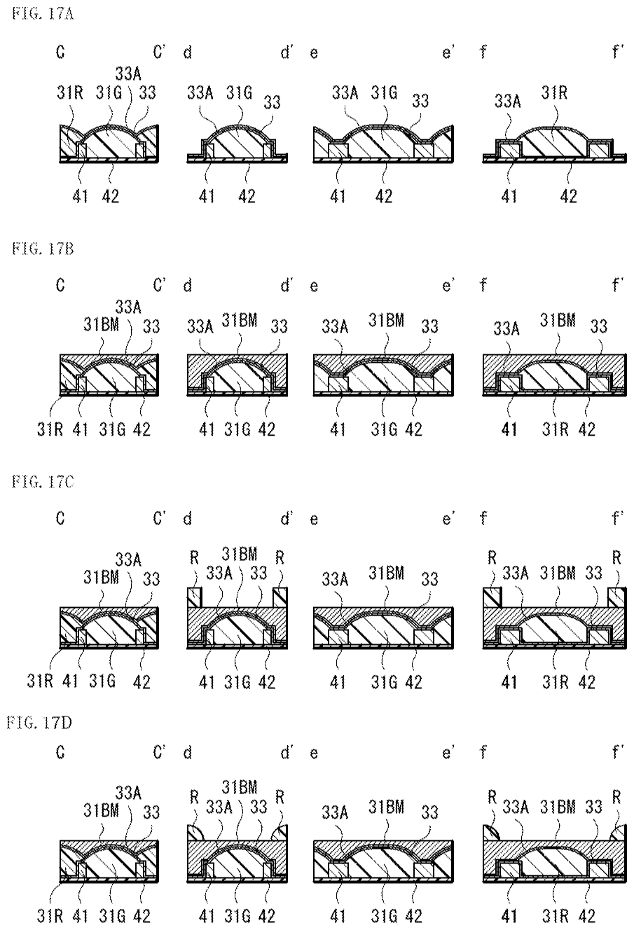

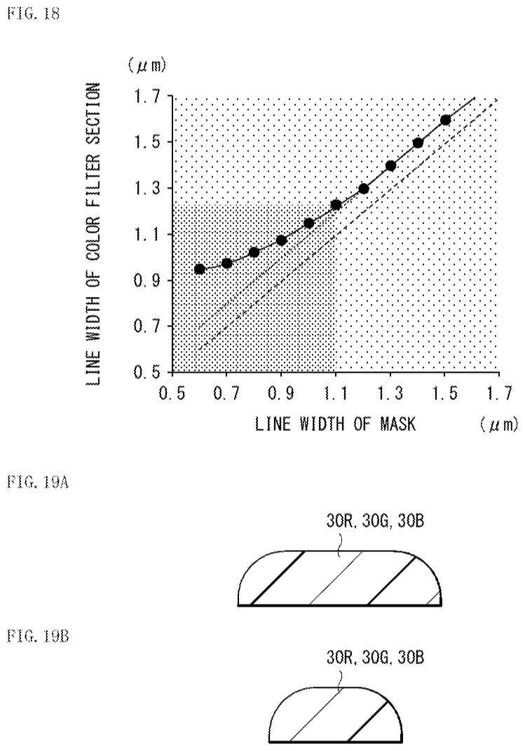

After the color filter section 31R is formed by using dry etching, the color filter section 31B may be formed by lithography (FIGS. 14C and 14D). Alternatively, the color filter section 31B may be formed by dry etching (FIGS. 17A to 17D).

After the color filter section 31R is formed (FIG. 14B), the stopper films 33A are formed that cover the color filter sections 31R and 316 as illustrated in FIG 17A. This forms the stopper films 33 and 33A on the surface of the color filter section 31G and forms the stopper film 33A on the surface of the color filter section 31R.

After the stopper film 33A is formed, the color filter material 31BM is applied and the color filter material 31BM is subsequently subjected to curing treatment as illustrated in FIG. 17B.

After the color filter material 3IBM is subjected to curing treatment, the resist pattern R having a predetermined shape is formed at the position corresponding to the blue pixel P as illustrated in FIG. 17C.

After the resist pattern R is formed, the resist pattern R is transformed into a lens shape as illustrated in FIG. 17D. Afterward, the resist pattern R is transferred to the color filter material 31BM, for example, by using dry etching. This forms the color filter section 31B (FIG. 14D). The color filter sections 31B is then formed at least partly in contact with the stopper film 33A of the adjacent color filter section 31G in an opposite side direction (d-d′) of the pixels P.

The color microlenses 30R, 30G, and 30B are formed in this way to complete the imaging device 10.

### (Operation of Imaging Device 10)

In the imaging device 10, pieces of light (e.g., pieces of light each having the wavelength in the visible region) are incident on the photodiodes 21 via the color microlenses 30R, 30G, and 30B. This causes each of the photodiode 21 to generate (photoelectrically convert) pairs of holes and electrons. Once the transfer transistor 22 is turned on, the signal charges accumulated in the photodiode 21 are transferred to the FD section 26. The FD section 26 converts the signal charges into voltage signals and reads each of these voltage signal as a pixel signal.

### (Workings and Effects of Imaging Device 10)

In the imaging device 10 according to the present embodiment, the color filter sections 31R, 31G. and 31B adjacent in the side directions (row direction and column direction) of the pixels P are in contact with each other. This reduces pieces of light incident on the photodiodes 21 without passing through the color filter sections 31R, 31G, and 31B. This makes it possible to suppress a decrease in sensitivity and the generation of a color mixture between the pixels P caused by the pieces of light incident on the photodiodes 21 without passing through the color filter sections 31R, 31G, and 31B.

In addition, the pixel array unit 12 of the imaging device 10 is provided with the phase difference detection pixel PA along with the pixel P and the imaging device 10 is compatible with the pupil division phase difference AF. Here, the first concave portions R1 are provided between the color microlenses 30R, 30G, and 30B adjacent in the side directions of the pixels P. The second concave portions R2 are provided between the color microlenses 30R, 30G, and 30B adjacent in the diagonal directions of the pixels P. The position H2 of each of the second concave portions R2 in the height direction is a position closer to the photodiode 21 than the position H1 of each of the first concave portions R1 in the height direction. This causes the radius of curvature (radius C2 of curvature in (B) of FIG. 22 below) of each of the color microlenses 30R, 30G, and 30B in the diagonal directions of the pixels P to approximate to the radius of curvature (radius C1 of curvature in (A) of FIG. 22 below) of each of the color microlenses 30R, 30G, and 30B in the opposite side directions of the pixels P, making it possible to increase the accuracy of pupil division phase difference AF (autofocus). The following describes this.

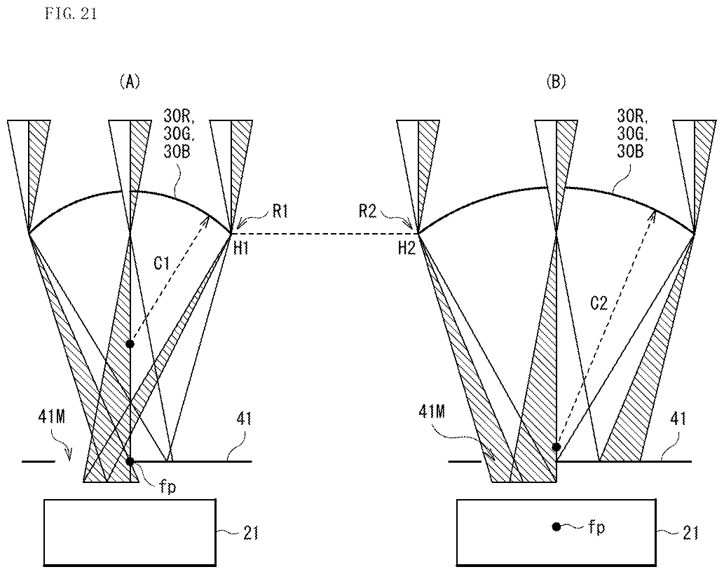

(A) and (B) of FIG. 21 each illustrate the relationships between the color microlenses 30R, 30G, and 30B disposed at the positions H1 and H2 that are the same in the height direction and the focal points (focal points fp) of the color microlenses 30R, 30G, and 30B.

In the phase difference detection pixel PA. the position of the focal point fp of each of the color microlenses 30R, 30G, and 30B is designed to be the same as the position of the light-shielding film 41 to separate the luminous fluxes from an exit pupil with accuracy ((A) of FIG. 21). This position of the focal point fp is influenced, for example, by the radius of curvature of each of the color microlenses 30R, 30G, and 30B. In a case where the positions H1 and H2 of the first concave portion RI and second concave portion R2 of each of the color microlenses 30R, 30G, and 30B in the height direction are the same, the color microlenses 30R, 30G, and 30B in the diagonal directions of the phase difference detection pixels PA (pixels P) each have the radius C2 of curvature greater than the radius C1 of curvature of each of the color microlenses 30R, 30G, and 30B in the opposite side directions of the phase difference detection pixels PA. Adjusting the position of the focal point fp in accordance with the radius C1 of curvature therefore causes the position of the focal point fp to be a position closer to the photodiode 21 than the light-shielding film 41 in a diagonal direction of the phase difference detection pixel PA ((B) of FIG. 21). This increases the focal length and decreases, for example, the accuracy of separating the left and right luminous fluxes.

In contrast, in the imaging device 10, the position H2 of the second concave portion R2 in the height direction is a position closer by the distance D to the photodiode 21 than the position H1 of the first concave portion R1 in the height direction as illustrated in (A) and (B) of FIG. 22. Accordingly, the radius C2 of curvature ((B) of FIG. 22) of each of the color microlenses 30R, 30G, and 30B in a diagonal direction of the phase difference detection pixels PA approximates to the radius CI of curvature ((A) of FIG. 22) of each of the color microlenses 30R, 30G, and 30B in an opposite side direction of the phase difference detection pixels PA. This also brings the position of the focal point fp in the diagonal direction of the phase difference detection pixels PA closer to the light-shielding film 41, making it possible to increase the accuracy of separating the left and right luminous fluxes.

It is preferable that these radii C1 and C2 of curvature of each of the color microlenses 30R, 30G, and 30B satisfy the following expression (1).

0.8×C1≤C2≤1.2×C1 (1)

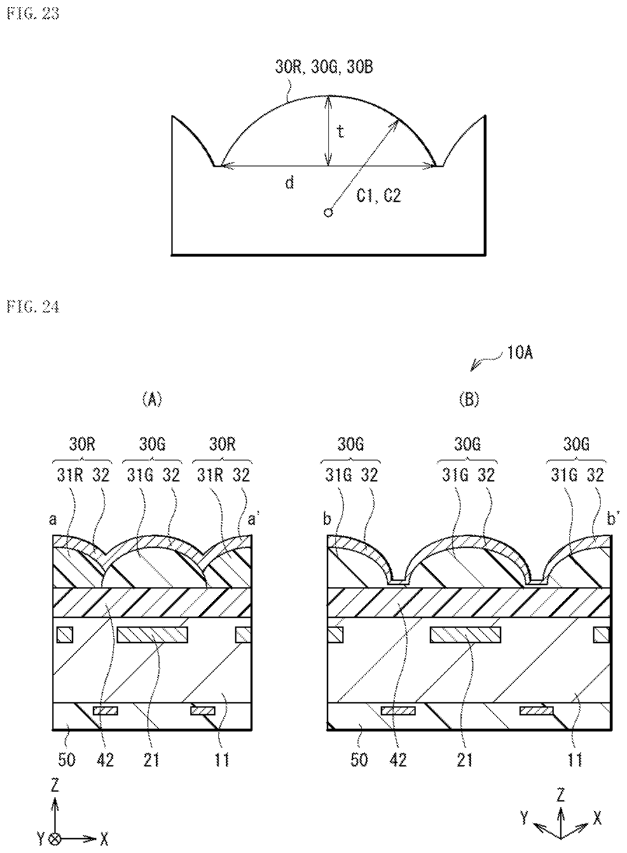

FIG. 23 illustrates the relationship between the radii C1 and C2 of curvature and the shape of each of the color microlenses 30R, 30G, and 30B. For example, the color microlenses 30R, 30G, and 30B each have width d and height t. The width d is the maximum width of each of the color microlenses 30R, 30G, and 30B and the height t is the maximum height of each of the color microlenses 30R, 30G, and 30B. The radii C1 and C2 of curvature of each of the color microlenses 30R, 30G, and 30B are obtained, for example, by using the following expression (2).

C1 and C2=(d²+4t²)/8 (2)

It is to be noted that the radii C1 and C2 of curvature here each include not only the radius of curvature of a lens shape included in a portion of a perfect circle, but also the radius of curvature of a lens shape included in an approximate circle.

In addition, in the imaging device 10, the color microlenses 30R, 30G, and 30B adjacent in the opposite side directions of the pixels P are in contact with each other in a plan view. Additionally, the gaps C (FIG. 3B) of the color microlenses 30R, 30G, and 30B adjacent in the diagonal directions of the pixels P are also small. The size of each of the gaps C is, for example, less than or equal to the wavelength of light in the visible region. That is, the color microlenses 30R, 30G, and 30B provided to the respective pixels P have a large effective area. This makes it possible to increase a light reception region in size and increase the detection accuracy of the pupil division phase difference AF.

As described above, in the present embodiment, the color filter sections 31R, 31G, and 31B adjacent in the opposite side directions of the pixels P are in contact with each other. This makes it possible to suppress a decrease in sensitivity and the generation of a color mixture between the pixels P caused by pieces of light incident on the photodiodes without passing through the color filter sections 31R, 31G, and 31B. It is thus possible to increase the sensitivity and suppress the generation of a color mixture between the adjacent pixels P.

In addition, in the imaging device 10, the position H2 of the second concave portion R2 of each of the color microlenses 30R, 30G, and 30B in the height direction is a position closer by the distance D to the photodiode 21 than the position H1 of the first concave portion R1 in the height direction. This causes the radius C2 of curvature of each of the color microlenses 30R, 30G, and 30B to approximate to the radius C1 of curvature. This allows the phase difference detection pixel PA to separate luminous fluxes with accuracy and makes it possible to increase the detection accuracy of the pupil division phase difference AF.

Further, the color microlenses 301R, 30G, and 30B adjacent in the opposite side directions of the pixels P are provided in contact with each other in a plan view. Additionally, the gaps C of the color microlenses 30R, 30G, and 30B adjacent in the diagonal directions of the pixels P are also sufficiently small, This increases the effective area of the color microlenses 30R, 30G, and 30B in size. The light reception region is thus enlarged to make it possible to further increase the detection accuracy of the pupil division phase difference AF.

Additionally, the color microlenses 30R, 30G, and 30B each have a light dispersing function and a light condensing function. This makes it possible to decrease the imaging device 10 in height as compared with a color filter and microlens that are separately provided, allowing the sensitivity characteristic to be increased.

In addition, it is possible to form the color filter sections 31R, 31G, and 31B each having a lens shape in the substantially square pixels P each having a side of 1.1 μm or less by using general lithography. This eliminates the necessity of a gray tone photomask or the like and makes it possible to easily manufacture the color filter sections 31R, 31G, and 31B each having a lens shape at low cost.

Further, the color filter sections 31R, 31G, and 31B adjacent in the opposite side directions of the pixels P are provided in contact with each other at least partly in the thickness direction. This reduces the time for forming the inorganic film 32 and makes it possible to suppress the manufacturing cost.

The following describes modification examples of the above-described first embodiment and another embodiment, but the following description provides the same components as those in the above-described first embodiment with the same reference signs and omits the description thereof as appropriate.

### MODIFICATION EXAMPLE 1

(A) and (B) of FIG. 24 each illustrate a schematic cross-sectional configuration of an imaging device (imaging device 10A) according to a modification example 1 of the above-described first embodiment. (A) of FIG. 24 corresponds to the cross-sectional configuration taken along the a-a′ line in FIGS. 3A and (B) of FIG. 24 corresponds to the cross-sectional configuration taken along the b-b′ line in FIG. 3A. In this imaging device 10A, the color filter sections 31G adjacent in the diagonal directions of the quadrangular pixels P are provided by being linked. Except for this point, the imaging device 10A according to the modification example 1 has a configuration similar to that of the imaging device 10 according to the above-described first embodiment. The workings and effects of the imaging device 10A are also similar.

As in the above-described imaging device 10, in the imaging device 10A, the color filter sections 31R, 31G. and 31B are disposed, for example, in Bayer arrangement ((A) of FIG. 3), In Bayer arrangement, the plurality of color filter sections 31G is continuously disposed along the diagonal directions of the quadrangular pixels P. These color filter sections 31G are linked to each other. In other words, the color filter sections 31G are provided between the pixels P adjacent in the diagonal directions.

### MODIFICATION EXAMPLE 2

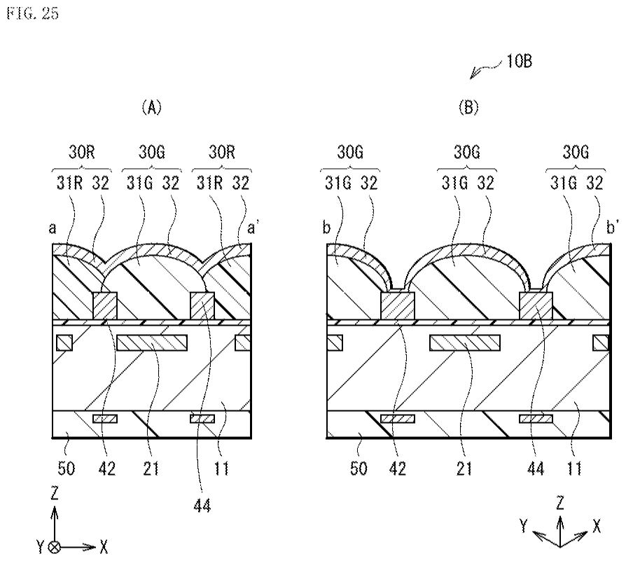

(A) and (B) of FIG. 25 each illustrate a schematic cross-sectional configuration of an imaging device (imaging device 10B) according to a modification example 2 of the above-described first embodiment. (A) of FIG. 25 corresponds to the cross-sectional configuration taken along the a-a′ line in FIG. 3A and (B) of FIG. 25 corresponds to the cross-sectional configuration taken along the b-b′ line in FIG. 3A. This imaging device 10B includes the light reflection film 44 between the color microlenses 30R, 30G, and 30B and the planarization film 42. This forms a waveguide structure. Except for this point, the imaging device 10B according to the modification example 2 has a configuration similar to that of the imaging device 10 according to the above-described first embodiment. The workings and effects of the imaging device 10B are also similar.

The waveguide structure provided to the imaging device 10B guides light incident on each of the color microlenses 30R, 30G, and 30B to the photodiode 21. In this waveguide structure, the light reflection film 44 is provided between the adjacent pixels P. The light reflection film 44 is provided between the color microlenses 30R, 30G, and 30B adjacent in the opposite side directions and diagonal directions of the pixels P. For example, the ends of the color filter sections 31R, 31G, and 31B are disposed on the light reflection film 44. The color filter sections 31R, 31G, and 31B adjacent in the opposite side directions of the pixels P are in contact with each other on the light reflection film 44 ((A) of FIG. 25). For example, the inorganic film 32 is provided on the light reflection film 44 between the color microlenses 30R, 30G, and 30B adjacent in the diagonal directions of the pixels P. As described above in the above-described modification example 1, the color filter sections 31G may be provided between the color microlens 30G adjacent in the diagonal directions of the pixels P.

The light reflection film 44 includes, for example, a low refractive index material having a lower refractive index than the refractive index of each of the color filter sections 31R, 31G, and 31B. For example, the color filter sections 31R, 31G, and 31B each have a refractive index of about 1.56 to 1.8. The low refractive index material included in the light reflection film 44 is, for example, silicon oxide (SiO), a resin containing fluorine, or the like. Examples of the resin containing fluorine include an acryl-based resin containing fluorine, a siloxane-based resin containing fluorine, and the like. Porous silica nanoparticles dispersed in such a resin containing fluorine may be included in the light reflection film 44. The light reflection film 44 may include, for example, a metal material having light reflectivity or the like.

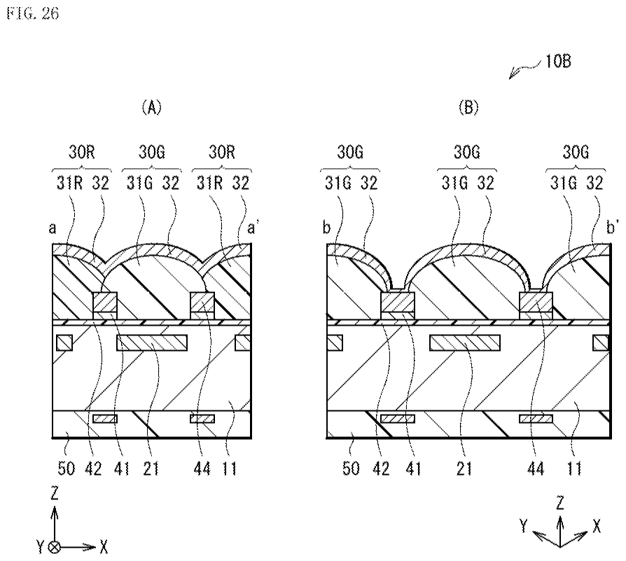

As illustrated in (A) and (B) of FIG. 26, the light reflection film 44 and the light-shielding film 41 may be provided between the color microlenses 30R, 30G, and 30B and the planarization film 42. This imaging device 10B includes, for example, the light-shielding film 41 and the light reflection film 44 in this order from the planarization film 42 side.

### MODIFICATION EXAMPLE 3

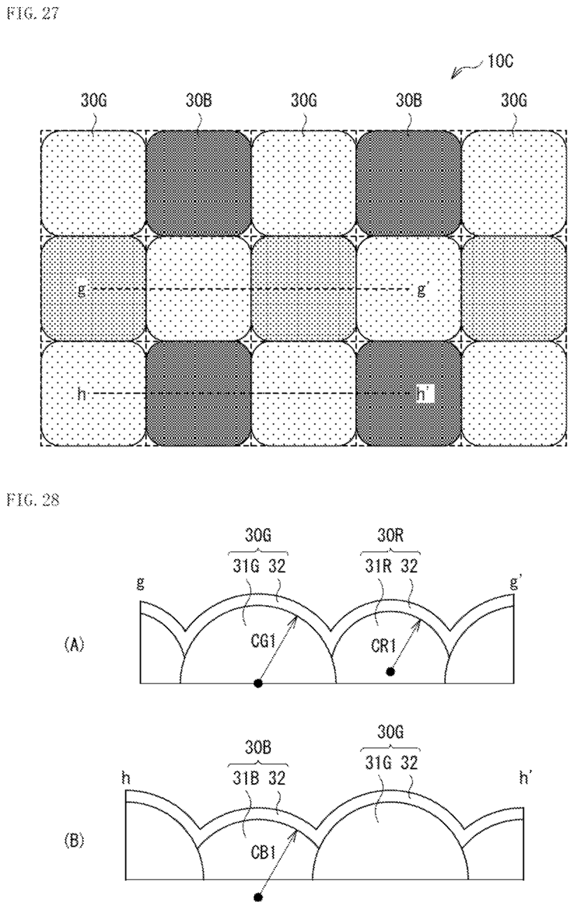

FIGS. 27 and (A) and (B) of FIG. 28 each illustrate the configuration of an imaging device (imaging device 1 OC) according to a modification example 3 of the above-described first embodiment, FIG 27 illustrates the planar configuration of the imaging device 10C. (A) of FIG. 28 illustrates the cross-sectional configuration taken along the g-g′ line illustrated in FIG. 27. (B) of FIG. 28 illustrates the cross-sectional configuration taken along the h-h′ line illustrated in FIG. 27. The color microlenses 30R, 300, and 30B of this imaging device 10C have radii of curvature (radii CR, CG, and CB of curvature described below) different between the respective colors. Except for this point, the imaging device 10C according to the modification example 3 has a configuration similar to that of the imaging device 10 according to the above-described first embodiment. The workings and effects of the imaging device 10C are also similar.

The color filter section 31R, the color filter section 310, and the color filter section 31B respectively have a radius CR1 of curvature, a radius CG1 of curvature, and a radius CB1 of curvature in an opposite side direction of the pixel P. These radii CR1, CG1, and CB1 of curvature are values different from each other and satisfy, for example, the relationship defined by the following expression (3).

CR1<CG1<CB1 (3)

The inorganic film 32 covering these color filter sections 31R, 31G, and 31B each having a lens shape is provided along the shape of each of the color filter sections 31R, 310, and 31B. The radius CR of curvature of the color microlens 30R, the radius CG of curvature of the color microlens 30G, and the radius CB of curvature of the color microlens 30B in an opposite side direction of the pixel P are thus values different from each other and satisfy, for example, the relationship defined by the following expression (4).

CR<CG<CB (4)

Adjusting the radii CR, CG, and CB of curvature of the color microlenses 30R, 30G, and 30B for the respective colors in this way makes it possible to correct chromatic aberration.

### MODIFICATION EXAMPLE 4

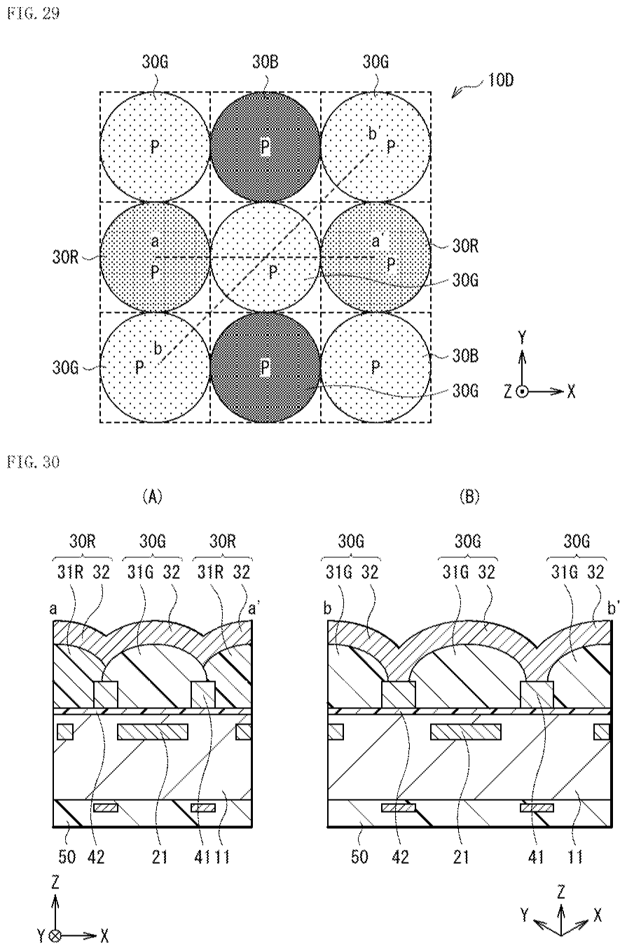

FIGS. 29 and (A) and (B) of FIG. 30 each illustrate the configuration of an imaging device (imaging device 10D) according to a modification example 4 of the above-described first embodiment. FIG. 29 illustrates the planar configuration of the imaging device 10D. (A) of FIG. 30 illustrates the cross-sectional configuration taken along the a-a′ line illustrated in FIG. 29. (B) of FIG. 30 illustrates the cross-sectional configuration taken along the b-b′ line illustrated in FIG. 29. The color microlenses 30R, 30G, and 30B of this imaging device 10D each have a substantially circular planar shape. Except for this point, the imaging device 10D according to the modification example 4 has a configuration similar to that of the imaging device 10 according to the above-described first embodiment. The workings and effects of the imaging device 10D are also similar.

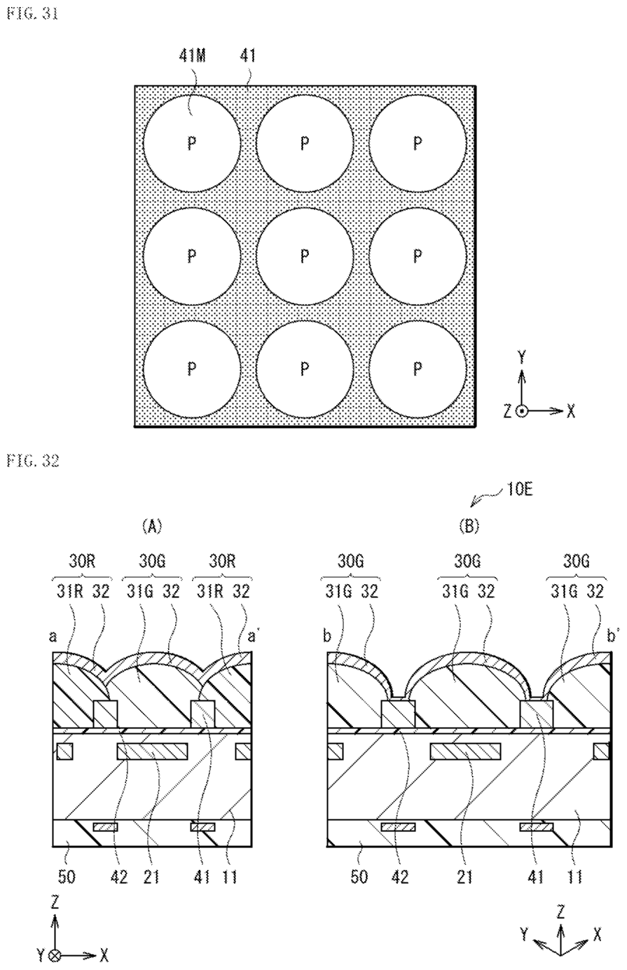

FIG. 31 illustrates the planar configuration of the light-shielding film 41 provided to the imaging device 10D. The light-shielding film 41 has, for example, the circular opening 41M for each pixel P. The color filter sections 31R, 31G, and 31B are each provided to fill this circular opening 41M ((A) and (B) of FIG. 30). That is, the color filter sections 31R, 31G, and 31B each have a substantially circular planar shape. The color filter sections 31R, 31G, and 31B adjacent in the opposite side directions of the quadrangular pixels P are in contact with each other at least partly in the thickness direction ((A) of FIG. 30). For example, the light-shielding film 41 is provided between the color filter sections 31R, 31G, and 31B adjacent in the diagonal directions of the pixels P ((B) of FIG. 30). The diameter of each of the circular color filter sections 31R, 31G, and 31B is, for example, substantially the same as the length of a side of the pixel P (FIG. 29).

The radius C2 of curvature ((B) of FIG. 22) of each of the color microlenses 30R, 30G, and 30B each having a substantially circular planar shape in a diagonal direction of the pixel P further approximates to the radius C1 of curvature ((A) of FIG. 22) in an opposite side direction of the pixel P. This makes it possible to further increase the detection accuracy of the pupil division phase difference AF.

### MODIFICATION EXAMPLE 5

(A) and (B) of FIG. 32 each illustrate a schematic cross-sectional configuration of an imaging device (imaging device 10E) according to a modification example 5 of the above-described first embodiment. (A) of FIG. 32 corresponds to the cross-sectional configuration taken along the a-a′ line in FIGS. 3A and (B) of FIG. 32 corresponds to the cross-sectional configuration taken along the b-b′ line in FIG. 3A. This imaging device 10E has the color filter section 31R (or the color filter section 31B) formed before the color filter section 31G. Except for this point, the imaging device 10E according to the modification example 5 has a configuration similar to that of the imaging device 10 according to the above-described first embodiment. The workings and effects of the imaging device 10E are also similar.

In the imaging device 10E, the color filter sections 31R, 31G, and 31B adjacent in the opposite side directions of the quadrangular pixels P are provided to partly overlap with each other. The color filter section 31G is disposed on the color filter section 31R (or the color filter section 31B) ((A) of FIG. 32).

### MODIFICATION EXAMPLE 6

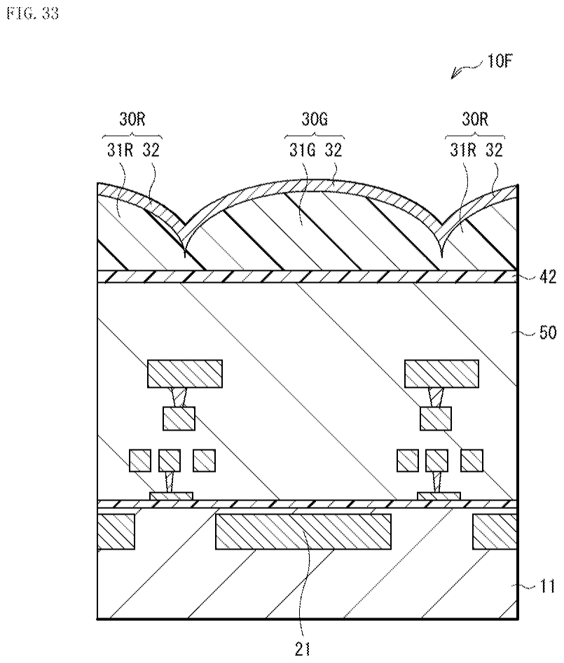

FIG. 33 illustrates a schematic cross-sectional configuration of an imaging device (imaging device 10F) according to a modification example 6 of the above-described first embodiment. This imaging device 10F is a front-illuminated imaging device. The imaging device 10F includes the wiring layer 50 between the semiconductor substrate 11 and the color microlenses 30R, 30G, and 30B. Except for this point, the imaging device 10F according to the modification example 6 has a configuration similar to that of the imaging device 10 according to the above-described first embodiment. The workings and effects of the imaging device 10F are also similar.

### MODIFICATION EXAMPLE 7

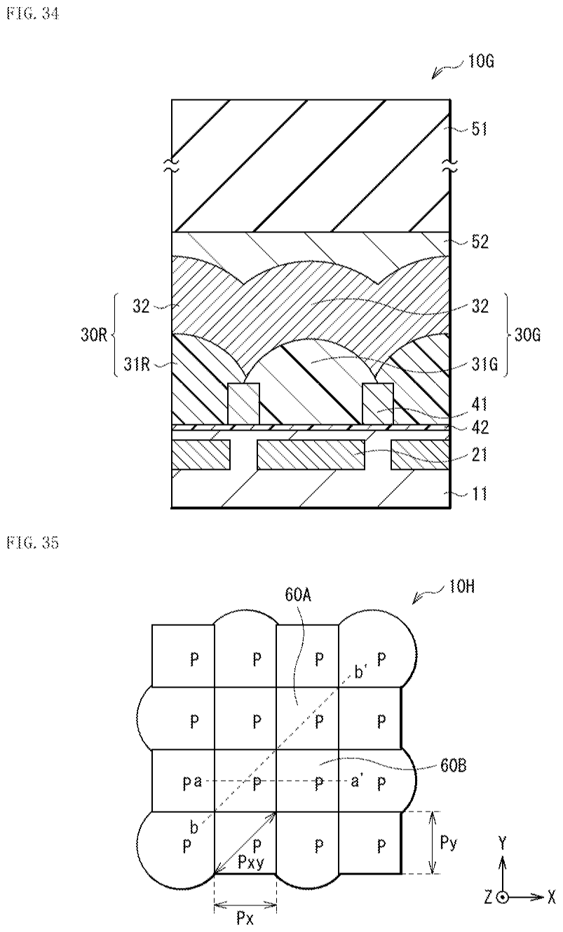

FIG. 34 illustrates a schematic cross-sectional configuration of an imaging device (imaging device 10G) according to a modification example 7 of the above-described first embodiment. This imaging device 10G is WCSP. The imaging device 10G includes a protective substrate 51 opposed to the semiconductor substrate 11 with the color microlenses 30R, 30G, and 30B interposed therebetween. Except for this point, the imaging device 10G according to the modification example 7 has a configuration similar to that of the imaging device 10 according to the above-described first embodiment. The workings and effects of the imaging device 10G are also similar.

The protective substrate 51 includes, for example, a glass substrate. The imaging device 10G includes the low refractive index layer 52 between the protective substrate 51 and the color microlenses 30R, 30G, and 30B. The low refractive index layer 52 includes, for example, an acryl-based resin containing fluorine, a siloxane resin containing fluorine, or the like. Porous silica nanoparticles dispersed in such a resin may be included in the low refractive index layer 52.

### Second Embodiment

FIG. 35 and (A) and (B) of FIG. 36 each schematically illustrate the configuration of a main unit of an imaging device (imaging device 10H) according to a second embodiment of the present disclosure. FIG. 35 illustrates the planar configuration of the imaging device 10H. (A) of FIG. 36 corresponds the cross-sectional configuration taken along the a-a′ line in FIG. 35. (B) of FIG. 36 corresponds the cross-sectional configuration taken along the b-b′ line in FIG. 35. This imaging device 10H includes a color filter layer 71 and microlenses (first microlens 60A and second microlens 60B) on the light incidence side of the photodiode 21. That is, the imaging device 10H separately has a light dispersing function and a light condensing function. Except for this point, the imaging device 10H according to the second embodiment has a configuration similar to that of the imaging device 10 according to the above-described first embodiment. The workings and effects of the imaging device 10H are also similar.

The imaging device 10H includes, for example, an insulating film 42A, the light-shielding film 41, a planarization film 42B, the color filter layer 71, a planarization film 72, the first microlens 60A, and the second microlens 60B in this order from the semiconductor substrate 11 side.

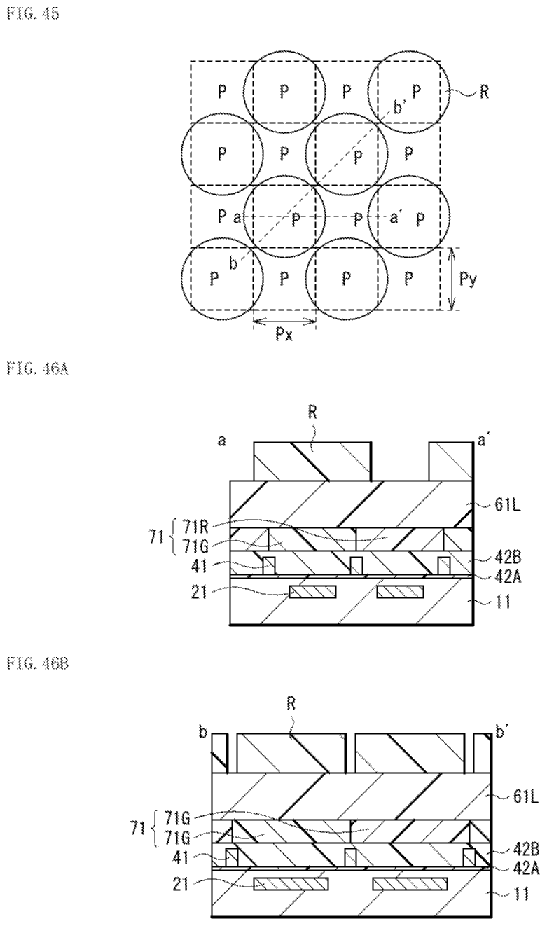

The insulating film 42A is provided between the light-shielding film 41 and the semiconductor substrate 11. The planarization film 42B is provided between the insulating film 42A and the color filter layer 71. The planarization film 72 is provided between the color filter layer 71 and the first microlens 60A and the second microlens 60B. This insulating film 42A includes, for example, a single-layer film of silicon oxide (SiO) or the like. The insulating film 42A may include a stacked film. The insulating film 42A may include, for example, a stacked film of hafnium oxide (Hf₂O) and silicon oxide (SiO). The insulating film 42A having a stacked structure of a plurality of films having different refractive indices in this way causes the insulating film 42A to function as an antireflection film. The planarization films 42B and 72 each include, for example, an organic material such as an acryl-based resin. For example, in a case where the first microlens 60A and the second microlens 60B (more specifically, the first lens section 61A and second lens section 61B described below) are formed by using dry etching (see FIGS. 45 to 54B below), the imaging device 101-1 does not have to include the planarization film 72 between the color filter layer 71 and the first microlens 60A and the second microlens 60B.

The color filter layer 71 provided between the planarization film 42B and the planarization film 72 has a light dispersing function. This color filter layer 71 includes, for example, color filters 71R, 71G, and 71B (see FIG. 57 below), The pixel P (red pixel) provided with the color filter 71R obtains the received-light data of light within the red wavelength range by using the photodiode 21. The pixel P (green pixel) provided with the color filter 71 obtains the received-light data of light within the green wavelength range. The pixel P (blue pixel) provided with the color filter 71B obtains the received-light data of light within the blue wavelength range. The color filters 71R, 71G, and 71B are disposed, for example, in Bayer arrangement. The color filters 71G are continuously disposed along the diagonal directions of the quadrangular pixels P. The color filter layer 71 includes, for example, a resin material and a pigment or a dye. Examples of the resin material include an acryl-based resin, a phenol-based resin, and the like. The color filter layer 71 may include such resin materials copolymerized with each other.

The first microlens 60A and the second microlens 60B each have a light condensing function. The first microlens 60A and the second microlens 60B are each opposed to the substrate 11 with the color filter layer 71 interposed therebetween. The first microlens 60A and the second microlens 60B are each embedded, for example, in an opening (opening 41M in FIG. 7) of the light-shielding film 41. The first microlens 60A includes the first lens section 61A and an inorganic film 62. The second microlens 60B includes the second lens section 61B and the inorganic film 62. The first microlenses 60A are disposed, for example, at the pixels P (green pixels) provided with the color filters 71G and the second microlenses 60B are disposed, for example, at the pixels P (red pixels and blue pixels) provided with the color filters 71R and 71B.

The planar shape of each pixel P is, for example, a quadrangle such as a square. The planar shape of each of the first microlens 60A and second microlens 60B is a quadrangle that has substantially the same size as the size of the pixel P. The sides of the pixels P are provided substantially in parallel with the arrangement directions (row direction and column direction) of the pixels P. The first microlens 60A and the second microlens 60B are each provided without substantially chamfering the corner portions of the quadrangle. The corner portions of the pixels P are substantially covered with the first microlens 60A and the second microlens 60B. It is preferable that a gap between the adjacent first microlens 60A and second microlens 60B have the wavelength (e.g., 400 nm) of light in the visible region or less in a diagonal direction (e.g., direction inclined by 45° to the X direction and Y direction in FIG. 35 or third direction) of the quadrangular pixels P in a plan (XY plane in FIG. 35) view. The adjacent first microlens 60.A and second microlens 60B are in contact with each other in a plan view in the opposite side directions (e.g., X direction and Y direction in FIG. 35) of the quadrangular pixels P.

The first lens section 61A and the second lens section 61B each have a lens shape. Specifically, the first lens section 61A and the second lens section 61B each have a convex curved surface on the side opposite to the semiconductor substrate 11. Each pixel P is provided with any of these first lens section 61A and second lens section 61B, For example, the first lens sections 61A are continuously disposed in the diagonal directions of the quadrangular pixels P. The second lens sections 61B are disposed to cover the pixels P other than the pixels P provided with the first lens sections 61.A. The adjacent first lens section 61A and second lens section 61B may partly overlap with each other between the adjacent pixels P. For example, the second lens section 61B is provided on the first lens section 61A.

The planar shape of each of the first lens section 61A and the second lens section 61B is, for example, a quadrangle that is substantially the same size as the planar shape of the pixel P. In the present embodiment, the adjacent first lens section 61A and second lens section 61B (first lens section 61A and second lens section 61B in (A) of FIG. 36) in an opposite side direction of the quadrangular pixels P overlap with each other at least partly in the thickness direction (e.g., Z direction in (A) of FIG. 36). That is, almost all the regions are provided with the first lens sections 61A and the second lens sections 61B between the adjacent pixels P. This reduces pieces of light incident on the photodiodes 21 without passing through the first lens sections 61A or the second lens sections 61B. This makes it possible to suppress a decrease in sensitivity caused by the light incident on the photodiode 21 without passing through the first lens section 61A or the second lens section 61B.

The first lens section 61A is provided sticking out from each side of the quadrangular pixel P ((A) of FIG. 36) and fits into the quadrangular pixel P in the diagonal directions of the pixel P ((B) of FIG. 36). In other words, the size of the first lens section 61A is greater than the size (size P_{X} and size P_{Y} in FIG. 35) of the sides of each pixel P in the side directions (X direction and Y direction) of the pixel P. In the diagonal directions of the pixel P, the size of the first lens section 61A is substantially the same as the size (size P_{XY} in FIG. 35) of the pixel P in a diagonal direction of the pixel P. The second lens section 61B is provided to cover the area between the first lens sections 61A, The second lens section 61 partly overlaps with the first lens section 61A in the side directions of the pixel P. Although described in detail below, the first lens sections 61 arranged in the diagonal directions of the pixels P in this way are formed to stick out from the respective sides of the quadrangular pixels P in the present embodiment. This makes it possible to provide the first lens sections 61A and the second lens sections 61B substantially with no gaps.

The first lens section 61A and the second lens section 61B may each include an organic material or an inorganic material. Examples of the organic material include a siloxane-based resin, a styrene-based resin, an acryl-based resin, and the like. The first lens section 61A and the second lens section 61B may each include such resin materials copolymerized with each other. The first lens section 61A and the second lens section 61B may each include such a resin material containing a metal oxide filler. Examples of the metal oxide filler include zinc oxide (ZnO), zirconium oxide (ZrO), niobium oxide (NbO), titanium oxide (TiO), tin oxide (SnO), and the like. Examples of the inorganic material include silicon nitride (SiN), silicon oxynitride (SiON), and the like.

A material included in the first lens section 61A and a material included in the second lens section 61B may be different from each other. For example, the first lens section 61A may include an inorganic material and the second lens section 61B may include an organic material. For example, a material included in the first lens section 61A may have a higher refractive index than the refractive index of a material included in the second lens section 61B. If the refractive index of a material included in the first lens section 61A is higher than the refractive index of a material included in the second lens section 61B in this way, the position of the focal point is deviated to the front of a subject (so-called front focus). It is thus possible to favorably use this for the pupil division phase difference AF.

The inorganic film 62 covering the first lens section 61A and the second lens section 61B is provided, for example, as common to the first lens section 61A and the second lens section 61B. This inorganic film 62 increases the effective area of the first lens section 61A and second lens section 61B and is provided along the lens shape of each of the first lens section 61A and the second lens section 61B. The inorganic film 62 includes, for example, a silicon oxynitride film, a silicon oxide film, a silicon oxycarbide film (SiOC), a silicon nitride film (SiN), or the like. The inorganic film 62 has, for example, a thickness of about 5 nm to 200 nm. The inorganic film 62 may include a stacked film of a plurality of inorganic films (inorganic films 32A and 32B) (see (A) and (B) of FIG. 6).

The microlenses 60A and 60B including the first lens section 61A, the second lens section 61B, and the inorganic film 62 like these are provided with concave and convex portions along the lens shapes of the first lens section 61A and the second lens section 61B ((A) of FIG. 36 and (B) of FIG. 26). The first microlens 60A and the second microlens 60B are highest in the middle portions of the respective pixels P. The middle portions of the respective pixels P are provided with the convex portions of the first microlens 60A and second microlens 60B. The first microlens 60A and the second microlens 60B are gradually lower from the middle portions of the respective pixels P to the outside (adjacent pixels P side). The concave portions of the first microlens 60A and second microlens 60B are provided between the adjacent pixels P.

The first microlens 60A and the second microlens 60B have the first concave portion R1 between the first microlens 60A and the second microlens 60B (between the first microlens 60A and the second microlens 60B in (A) of FIG. 36) adjacent in an opposite side direction of the quadrangular pixels P. The first microlens 60A and the second microlens 60B have the second concave portion R2 between the first microlens 60A and the second microlens 60B (between the first microlenses 60A in (B) of FIG. 36) adjacent in a diagonal direction of the quadrangular pixels P. The position (position H1) of each of the first concave portions RI in the height direction (e.g., Z direction in (A) of FIG. 36) and the position (position H2) of each of the second concave portions R2 in the height direction are defined, for example, by the inorganic film 32. Here, this position H2 of the second concave portion R2 is lower than the position H1 of the first concave portion R1. The position H2 of the second concave portion R2 is a position closer by distance D to the photodiode 21 than the position H1 of the first concave portion R1. As described above in the above-described first embodiment, this causes the radius of curvature (radius C2 of curvature in (B) of FIG. 36) of each of the first microlens 60A and second microlens 60B in a diagonal direction of the quadrangular pixels P to approximate to the radius of curvature (radius C1 of curvature in (A) of FIG. 36) of each of the first microlens 60A and second microlens 60B in an opposite side direction of the quadrangular pixels P, making it possible to increase the accuracy of pupil division phase difference AF (autofocus).

Further, the shape of the first lens section 61A is defined with higher accuracy than that of the shape of the second lens section 61B. The radii C1 and C2 of curvature of the first microlens 60A thus satisfy, for example, the following expression (5).

0.9×C1≤C2≤1.1×C1 (5)

The imaging device 10H may be manufactured, for example, as follows.

The semiconductor substrate 11 including the photodiode 21 is first formed.

A transistor (FIG. 2) or the like is then formed on the semiconductor substrate 11. Afterward, the wiring layer 50 (see FIG. 4 or the like) is formed on one (surface opposite to the light incidence side) of the surfaces of the semiconductor substrate 11. Next, the insulating film 42A is formed on the other of the surfaces of the semiconductor substrate 11.

After the insulating film 42A is formed, the light-shielding film 41 and the planarization film 42B are formed in this order. The planarization film 42B is formed, for example, by using an acryl-based resin. The color filter layer 71 and the planarization film 72 are then formed in this order. The planarization film 72 is formed, for example, by using an acryl-based resin.

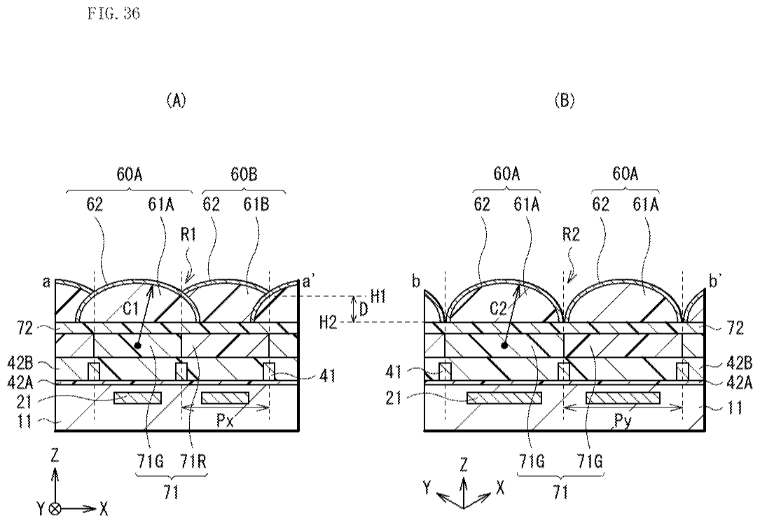

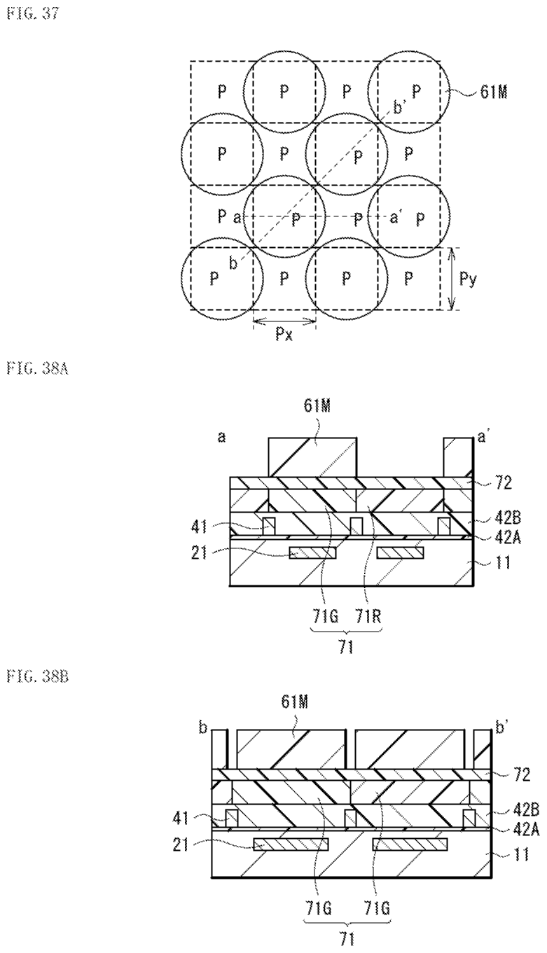

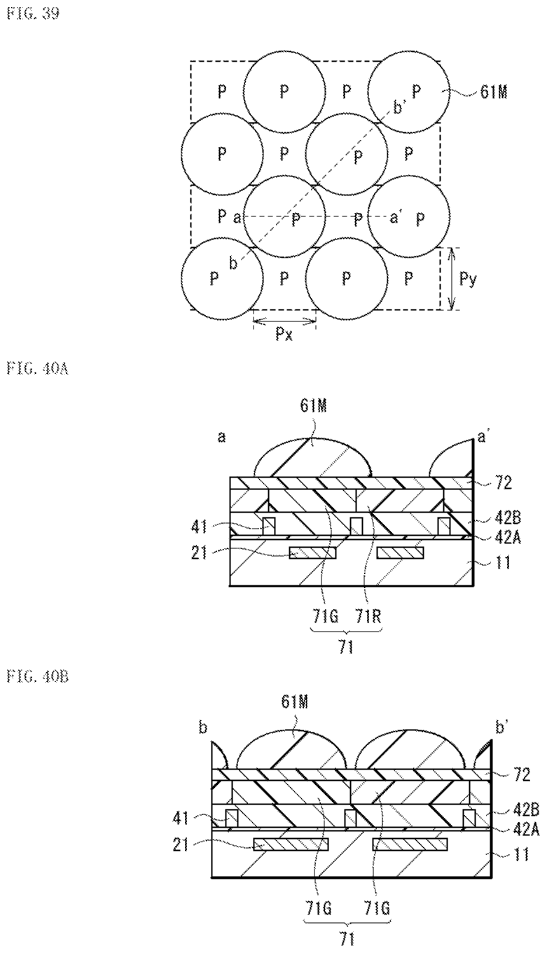

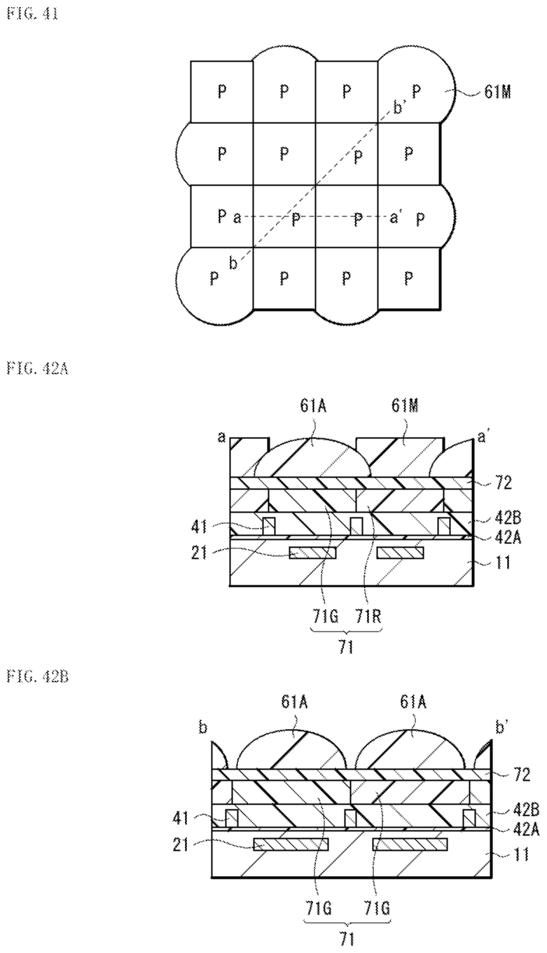

Next, the first lens section 61A and the second lens section 61B are formed on the planarization film 72. The following describes an example of a method of forming the first lens section 61A and the second lens section 61B with reference to FIGS. 37 to 44B. FIGS. 37, 39, 41, and 43 illustrate the planar configurations in the respective steps. FIGS. 38A and 38B illustrate the cross-sectional configurations taken along the a-a′ line and b-b′ line illustrated in FIG. 37. FIGS. 40A and 40B illustrate the cross-sectional configurations taken along the a-a′ line and b-b′ line illustrated in FIG. 39. FIGS. 42A and 42B illustrate the cross-sectional configurations taken along the a-a′ line and b-b′ line illustrated in FIG. 41. FIGS. 44A and 44B illustrate the cross-sectional configurations taken along the a-a′ line and b-b′ line illustrated in FIG. 37.

As illustrated in FIGS. 37, 38A, and 38B, for example, a pattern of a lens material M is first formed for the pixel P (green pixel) provided with the color filter 71G. The patterned lens material M then has, for example, a substantially circular planar shape. The diameter of this circle is greater than the size P_{X} and size P_{Y} of the sides of the pixel P. The lens materials M are disposed side by side, for example, in the diagonal directions of the pixels P. These lens materials M are each formed, for example, by coating the planarization film 72 with a photosensitive microlens material and then patterning this by using a polygonal mask having angles more than or equal to those of an octagon. The photosensitive microlens material is, for example, a positive photoresist. For example, photolithography is used for the patterning. The patterned lens materials M are irradiated, for example, with ultraviolet rays (bleaching treatment). This decomposes the photosensitive substances included in the lens materials M and makes it possible to increase the transmittance of light on the short wavelength side of the visible region.

Next, as illustrated in FIGS. 39, 40A, and 40B, the patterned lens materials M are each transformed into a lens shape. This forms the first lens section 61A. The lens shape is formed, for example, by subjecting the patterned lens material M to thermal reflow. The thermal reflow is performed, for example, at temperature higher than or equal to the thermal softening point of the photoresist. This temperature higher than or equal to the thermal softening point of the photoresist is, for example, about 120° C. to 180° C.

After the first lens sections 61A are formed, the patterns of the lens materials M are formed in the pixels P (red pixels and blue pixels) other than the pixels P (pixels P arranged in the diagonal directions of the pixels P) in which the first lens sections 61A are formed as illustrated in F1GS. 41, 42A, and 42B. To form this pattern of each of the lens materials M, the pattern of the lens material M is formed to partly overlap with the first lens section 61A in an opposite side direction of the pixel P. The pattern of the lens material M is formed, for example, by using photolithography. The patterned lens materials M are irradiated, for example, with ultraviolet rays (bleaching treatment).

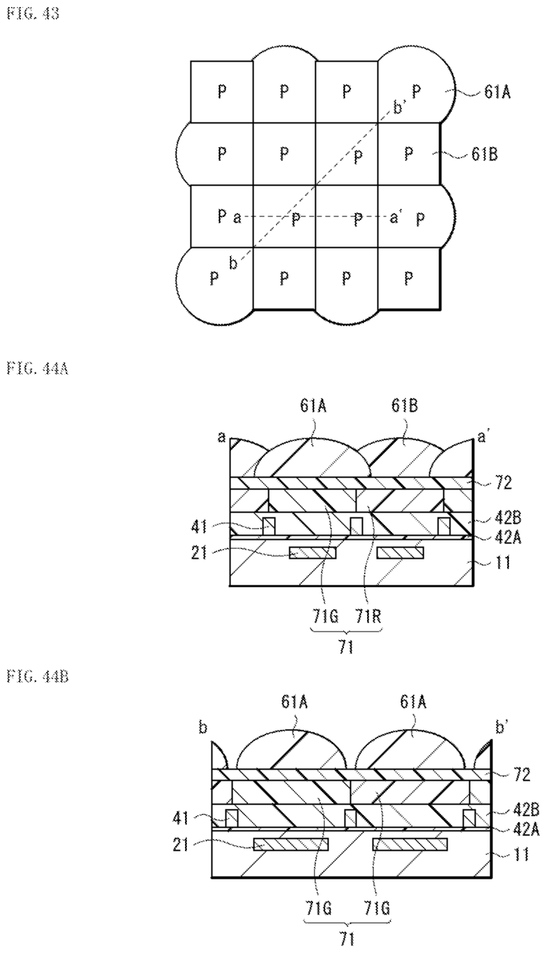

Next, as illustrated in FIGS. 43, 44A, and 44B, the patterned lens materials M are each transformed into a lens shape. This forms the second lens section 61B. The lens shape is formed, for example, by subjecting the patterned lens material M to thermal reflow. The thermal reflow is performed, for example, at temperature higher than or equal to the thermal softening point of the photoresist. This temperature higher than or equal to the thermal softening point of the photoresist is, for example, about 120° C. to 180° C.

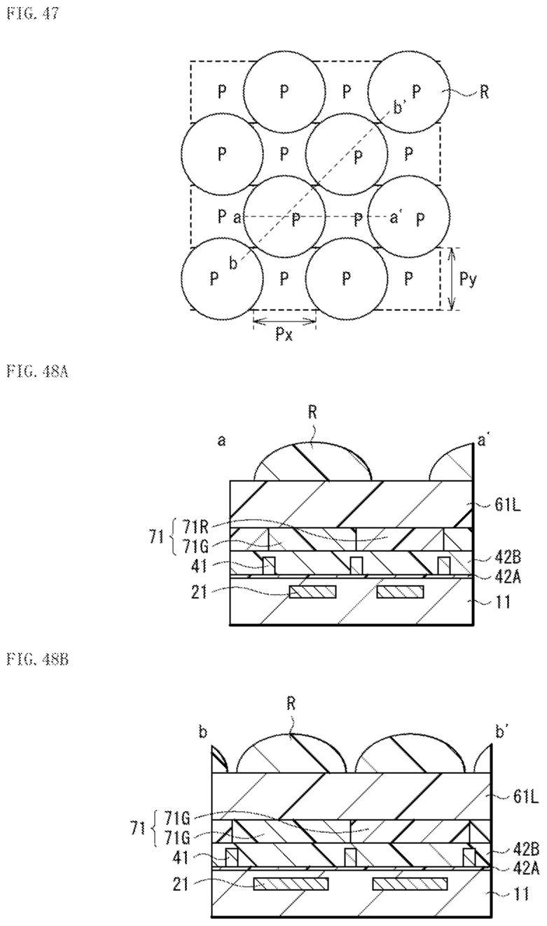

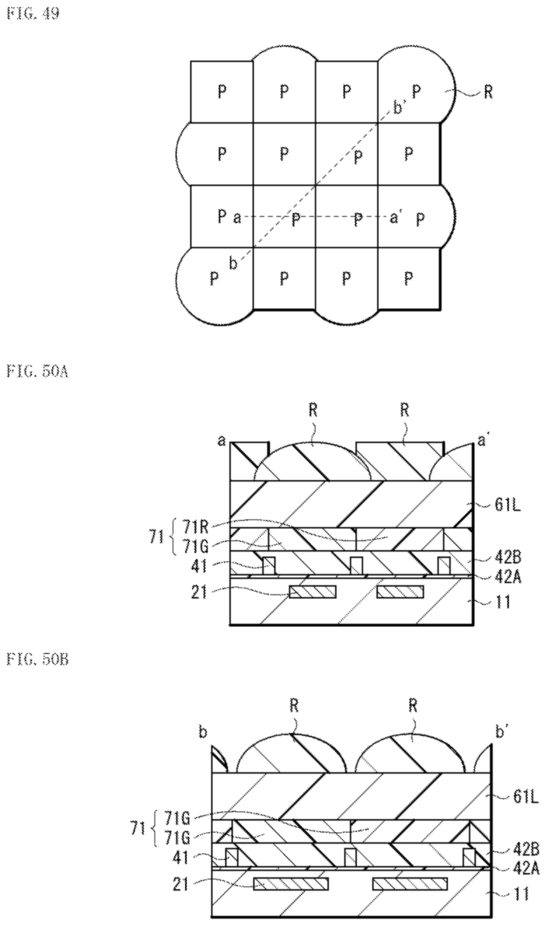

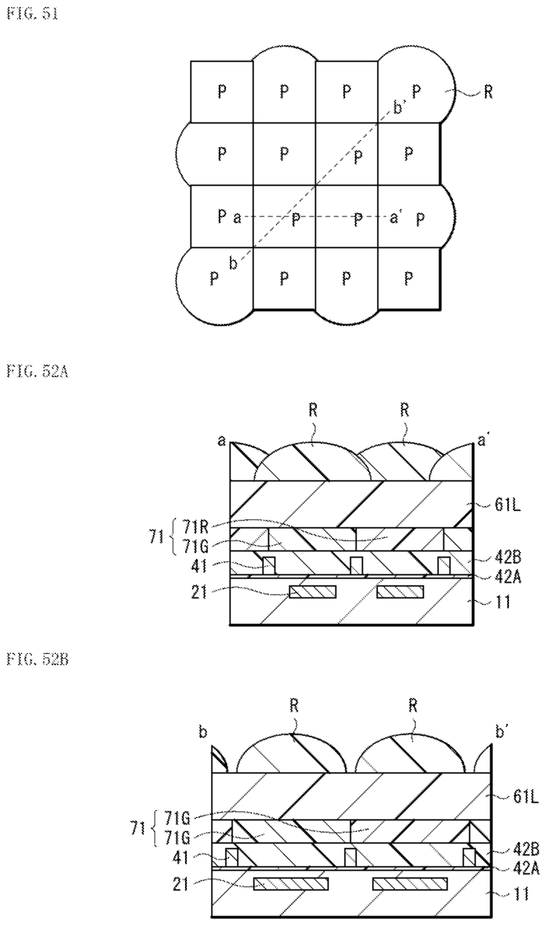

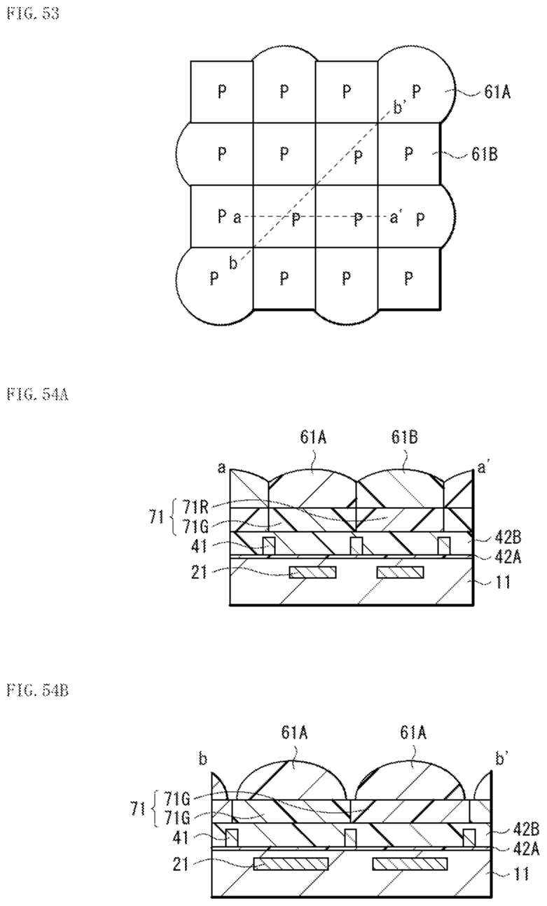

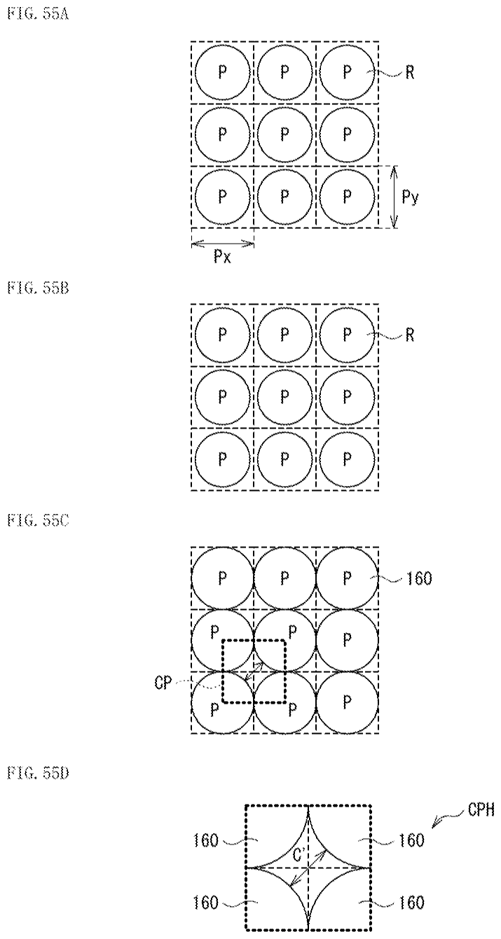

It is also possible to form the first lens section 61A and the lens section 61B by using a method other than the above-described method, FIGS. 45 to 54B each illustrate another example of the method of forming the first lens section 61A and the second lens section 61B. FIGS. 45, 47, 49, 51, and 53 illustrate the planar configurations in the respective steps. FIGS. 46A and 46B illustrate the cross-sectional configurations taken along the a-a′ line and b-b′ line illustrated in FIG. 45. FIGS. 48A and 48B illustrate the cross-sectional configurations taken along the a-4 line and b-b′ line illustrated in FIG. 47. FIGS. 50A and 50B illustrate the cross-sectional configurations taken along the a-a′ line and b-b′ line illustrated in FIG. 49, FIGS. 52A and 52B illustrate the cross-sectional configurations taken along the a-a′ line and b-b′ line illustrated in FIG. 51. FIGS. 54A and 54B illustrate the cross-sectional configurations taken along the a-a′ line and b-b′ line illustrated in FIG. 53.

After the color filter layer 71 is formed as described above, a lens material layer 61L is formed on the color filter layer 71. This lens material layer 61L is formed, for example, by coating the entire surface of the color filter layer 71 with an acryl-based resin, a styrene-based resin, a resin obtained by copolymerizing such resin materials, or the like.

After the lens material layer 61L is formed, the resist pattern R is formed for the pixel P (green pixel) provided with the color filter 71G as illustrated in FIGS. 45, 46A, and 46B. The resist pattern R has, for example, a substantially circular planar shape. The diameter of this circle is greater than the size P_{X} and size P_{Y} of the sides of the pixel P. The resist patterns R are disposed side by side, for example, in the diagonal directions of the pixels P. This resist pattern R is formed, for example, by coating the lens material layer 61L with a positive photoresist and then patterning this by using a polygonal mask having angles more than or equal to those of an octagon. For example, photolithography is used for the patterning.

After the resist pattern R is formed, the resist pattern R is transformed into a lens shape as illustrated in FIGS. 47, 48A, and 48B. The resist pattern R is transformed, for example, by subjecting the resist pattern R to thermal reflow. The thermal reflow is performed, for example, at temperature higher than or equal to the thermal softening point of the photoresist. This temperature higher than or equal to the thermal softening point of the photoresist is, for example, about 120° C. to 80° C.

Next, as illustrated in FIGS. 49, 50A, and 50B, the resist patterns R are formed in the pixels P (red pixels and blue pixels) other than the pixels P (pixels P arranged in the diagonal directions of the pixels P) in which the resist patterns R each having a lens shape are formed. In the pattern formation of this resist pattern R, the resist pattern. R is formed to partly overlap with the resist pattern R (resist pattern R provided to a green pixel) having a lens shape in an opposite side direction of the pixel P. The resist pattern R is formed, for example, by using photolithography.

Next, as illustrated in FIGS. 51, 52A, and 52B, this resist pattern R is transformed into a lens shape. The lens shape is formed, for example, by subjecting the resist pattern P to thermal reflow. The thermal reflow is performed, for example, at temperature higher than or equal to the thermal softening point of the photoresist. This temperature higher than or equal to the thermal softening point of the photoresist is, for example, about 120° C. to 180° C.

Next, as illustrated in FIGS. 53, 54A, and 54B, the microlens layer 611, is subjected to etch back by using the resist pattern R having a lens shape that is formed in two steps and the resist pattern R is removed. This transfers the shape of the resist pattern R to the microlens layer 61L to form each of the first lens section 61A and the second lens section 61B. For example, dry etching is used for the etch back.

Examples of apparatuses used for dry etching include a microwave plasma etching apparatus, a parallel plate RIE (Reactive Ion Etching) apparatus, a high-pressure narrow-gap plasma etching apparatus, an ECR. (Electron Cyclotron Resonance) etching apparatus, a transformer coupled plasma etching apparatus, an inductively coupled plasma etching apparatus, a helicon wave plasma etching apparatus, and the like. It is also possible to use a high-density plasma etching apparatus other than those described above. For example, carbon tetrafluoride (CF₄), nitrogen trifluoride (NF₃), sulfur hexafluoride (SF₆), octafluoropropane (C₃F₈), octafluorocyclobutane (C₄F₈), hexafluoro-1,3-butadiene (C₄F₆), octafluorocyclopentene (C₅F₈), hexafluoroethane (C₂F₆), or the like is usable for the etching gas.

In addition, it is also possible to form the first lens section 61A and the second lens section 61B by combining the above-described two methods. For example, after the lens material layer 61L is subjected to etch back to form the first lens section 61A by using the resist pattern R, the second lens section 61B may be formed by using a lens material 61M.

In this way, after the first lens section 61A and the second lens section 61B are formed, the inorganic film 62 covering the first lens section 61A and the second lens section 61B is formed. This forms the first microlens 60A and the second microlens 60B. Here, the first lens section 60A and second lens section 60B adjacent in an opposite side direction of the pixels P are provided in contact with each other. This reduces the time for forming the inorganic film 62 as compared with the first lens section 60A and second lens section 60B that are separated from each other. This makes it possible to reduce the manufacturing cost.

In the imaging device 10H according to the present embodiment, the first lens section 61A and second lens section 61B adjacent in the side directions (row direction and column direction) of the pixels P are in contact with each other. This reduces light incident on the photodiode 21 without passing through the first lens section 61A or the second lens section 61B. This makes it possible to suppress a decrease in sensitivity caused by the light incident on the photodiode 21 without passing through the first lens section 61A or the second lens section 61B.

Here, the first lens section 61A is formed to have greater size than the size P_{X} and size P_{Y} of the sides of the pixel P in the side directions of the pixel P This makes it possible to suppress an increase in manufacturing cost and the generation of a dark current (PID: Plasma Induced Damage) caused by a large amount of etch back. The following describes this.

FIGS. 55A to 55C illustrate a method of forming a microlens by using the resist pattern R having size that allows the resist pattern R to fit into the pixel P in order of steps. The resist pattern R having a substantially circular planar shape is first formed on the lens material layer (e.g., lens material layer 61L in FIGS. 46A and 46B) (FIG. 55A). The diameter of the planar shape of the resist pattern R is then less than the size P_{X} and size P_{Y} of the sides of the pixel P. Afterward, the resist pattern. R is subjected to thermal reflow (FIG. 55B) and the lens material layer is subjected to etch back to form the microlens (microlens 160) (FIG. 55C).

Such a method prevents the resist patterns R adjacent in an opposite side direction of the pixels P from coming into contact with each other after thermal reflow. This leaves a gap of at least about 0.2 μm to 0.3 μm between the resist patterns R adjacent in the opposite side direction of the pixels P, for example, in a case where lithography is performed by using an i line.

To eliminate this gap in the opposite side direction of the pixels P, a large amount of etch back is necessary. This large amount of etch back increases the manufacturing cost. In addition, the large amount of etch back more easily causes a dark current.

FIG. 55D is an enlarged view of a corner portion (corner portion CPH) illustrated in FIG. 55C. It is possible to express the gap C′ of the microlenses 160 adjacent in a diagonal direction of the pixels P among the microlenses 160 formed in this way, for example, as the following expression (6).

C′=P_{X}, P_{Y}×√(2−P_{X}, P_{Y}) (6)

Even if the pixels P have no gap in an opposite side direction, the pixels P still have the gap C′ expressed as the above-described expression (6) in a diagonal direction. This gap C′ increases as the size P_{X} and size P_{Y} of the sides of the pixel P increase, This decreases the sensitivity of the imaging device.

In addition, for example, in a case where the microlenses 160 are each formed by using an inorganic material, no CD (Critical Dimension) gain is generated. This is more likely generate a larger gap between the microlenses 160. To decrease this gap, it is necessary to add a microlens material. This increases the manufacturing cost. In addition, yields are decreased.

In contrast, in the imaging device 10H, the first lens section 61A is formed to have greater size than the size P_{X} and size P_{Y} of the sides of the pixel P. In addition, the second lens section 61B is formed to overlap with the first lens section 61B in an opposite side direction of the pixels P. This makes it possible to suppress an increase in manufacturing cost and the generation of a dark current caused by a large amount of etch back. Further, a gap of the first microlens 60A and second microlens 60B adjacent in an opposite side direction of the pixels P is less than or equal to the wavelength of the visible region, for example. It is thus possible to increase the sensitivity of the imaging device 10H. In addition, even if the first lens section 61A and the second lens section 61B are each formed by using an inorganic material, it is not necessary to add a lens material. This makes it possible to suppress an increase in manufacturing cost and a decrease in yields.

In addition, as with the imaging device 10 according to the above-described first embodiment, the position H2 of each of the second concave portions R2 in the height direction is a position closer to the photodiode 21 than the position H1 of each of the first concave portions R1 in the height direction. This causes the radius C2 of curvature of each of the first microlens 60A and second microlens 60B in a diagonal direction of the pixels P to approximate to the radius C1 of curvature of each of the first microlens 60A and second microlens 60B in an opposite side direction of the pixels P, making it possible to increase the accuracy of the pupil division phase difference AF.

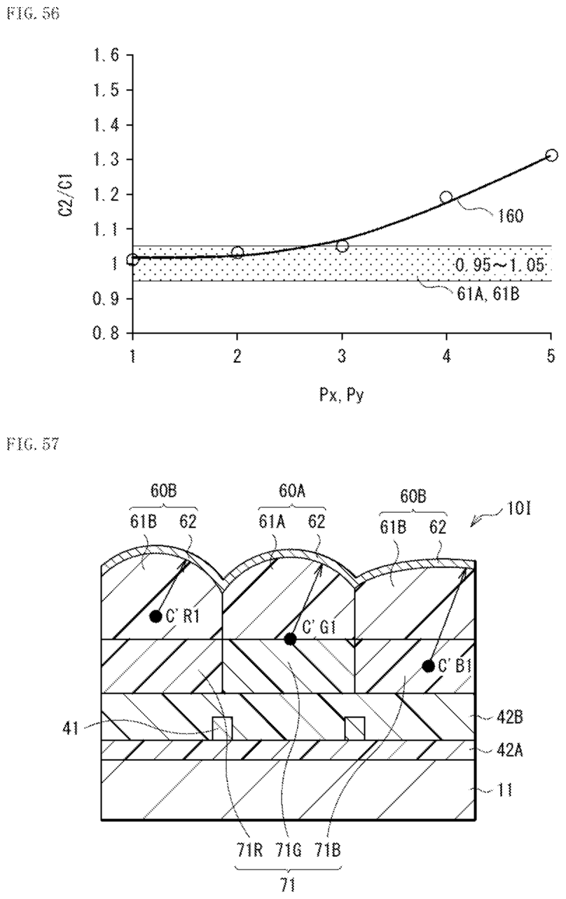

FIG. 56 illustrates examples of the radii C1 and C2 of curvature of the microlens 160 formed in the above-described method illustrated in FIGS. 55A to 55C. The vertical axis of FIG. 56 represents the radius C2 of curvature/the radius C1 of curvature and the horizontal axis represents the size P_{X} and size P_{Y} of the sides of the pixel P. In this way, the microlens 160 has a greater difference between the radius C1 of curvature and the radius C2 of curvature as the size P_{X} and size P_{Y} of the sides of the pixel P increase. This easily causes a decrease in the accuracy of the pupil division phase difference AF, In contrast, the radius C2 of curvature/the radius C1 of curvature of each of the first microlens 60A and the second microlens 60B is, for example, 0.98 to 1.05 regardless of the size P_{X} and size P_{Y} of the sides of the pixel P. This makes it possible to keep the high accuracy of the pupil division phase difference AF even if the size P_{X} and size P_{Y} of the sides of the pixel P increase.

As described above, in the present embodiment, the first lens section 61A and the second lens section 61B adjacent in an opposite side direction of the pixels P are in contact with each other. This makes it possible to suppress a decrease in sensitivity caused by pieces of light incident on the photodiodes without passing through the first lens section 61A and the second lens section 61B. It is thus possible to increase the sensitivity.

### MODIFICATION EXAMPLE 8

FIG. 57 illustrates the cross-sectional configuration of a main unit of an imaging device (imaging device 101) according to a modification example 8 of the above-described second embodiment. In this imaging device 10H, the first microlenses 60A and the second microlenses 60B have radii of curvature (radii C′R, C′G, and C′B of curvature described below) that are different between the respective colors of the color filters 71R, 71G, and 71B. Except for this point, the imaging device 10I according to the modification example 8 has a configuration similar to that of the imaging device 10H according to the above-described second embodiment. The workings and effects of the imaging device 101 are also similar.

In an opposite side direction of the pixels P, the second lens section 61B disposed at the pixel P (red pixel) provided with color filter 71R has a radius CR1 of curvature, the first lens section 61A disposed at the pixel P (green pixel) provided with the color filter 71G has a radius C′G1 of curvature, and the second lens section 61B provided to the pixel P (blue pixel) provided with the color filter 71B has a radius C′B1 of curvature. These radii C′R1, C′G1, and C′B1 of curvature are values different from each other and satisfy, for example, the relationship defined by the following expression (7).

C′R1<C′G1<C′B1 (7)

The inorganic film 72 covering these first lens section 61A and second lens section 61B each having a lens shape is provided along the shape of each of the first lens section 61A and the second lens section 61B. The radius CG of curvature of the first microlens 60A disposed at a green pixel, the radius C′R of curvature of the second microlens 60B disposed at a red pixel, and the radius C′B of curvature of the second microlens 60B disposed at a blue pixel thus are values different from each other and satisfy, for example, the relationship defined by the following expression (8).

C′R<C′G<C′B (8)

To adjust the radii C′R, C′G, and C′B of curvature, lens materials (e.g., lens materials M in FIGS. 38A and 38B) for forming the first lens section 61A and the second lens sections 61B may be different in thickness between a red pixel, a green pixel, and a blue pixel. Alternatively, materials included in the first lens section 61A and second lens sections 61B may have refractive indices different between a red pixel, a green pixel, and a blue pixel. For example, a material included in the second lens section 61B provided to a red pixel then has the highest refractive index and a material included in the first lens section 61A provided to a green pixel and a material included in the second lens section MB provided to a blue pixel have lower refractive indices in this order.

In this way, adjusting the radii C′R, CG, and C′B of curvature of the first microlenses 60A and the second microlenses 60B between a red pixel, a green pixel, and a blue pixel allows the chromatic aberration to be corrected. This improves the shading and makes it possible to increase the image quality.

### MODIFICATION EXAMPLE 9

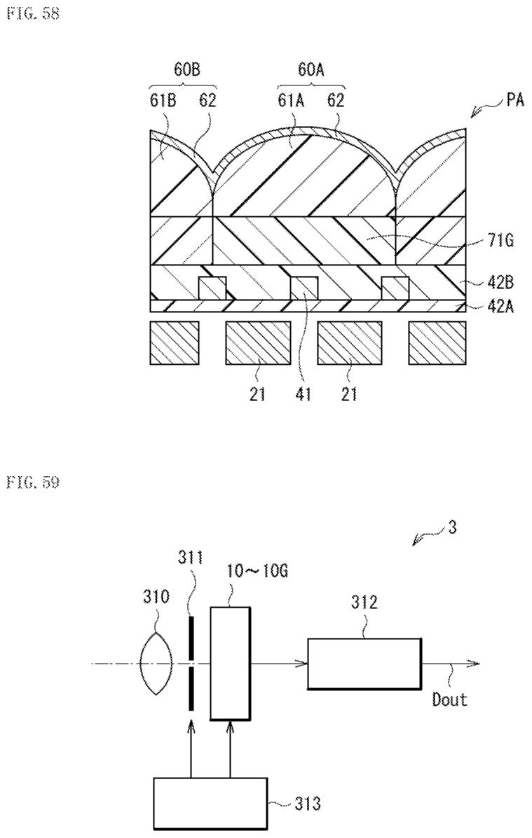

FIG. 58 schematically illustrates another example (modification example 9) of the cross-sectional configuration of the phase difference detection pixel PA. The phase difference detection pixel PA may be provided with the two photodiodes 21. Providing the phase difference detection pixel PA with the two photodiodes 21 makes it possible to further increase the accuracy of the pupil division phase difference AF. This phase difference detection pixel PA according to the modification example 9 may be provided to the imaging device 10 according to the above-described first embodiment or the imaging device 101-1 according to the above-described second embodiment.

It is preferable that the phase difference detection pixel PA be disposed, for example, at the pixel P (green pixel) provided with the first lens section 61A. This causes the entire effective surface to be detected for a phase difference. It is thus possible to further increase the accuracy of the pupil division phase difference AF.

### OTHER MODIFICATION EXAMPLES

The imaging device 10H according to the above-described second embodiment is applicable to a modification example similar to the above-described first embodiment. For example, the imaging device 10H may be a back-illuminated imaging device or a front-illuminated (see FIG. 33) imaging device. In addition, the imaging device 10H may also be applied to WCSP (see FIG. 34), it is easy in the imaging device 10H to form the first lens section 61A and the second lens section 61B each including, for example, a high refractive index material such as an inorganic material and the imaging device 10H is thus favorably usable for WCSP.

### APPLIED EXAMPLE

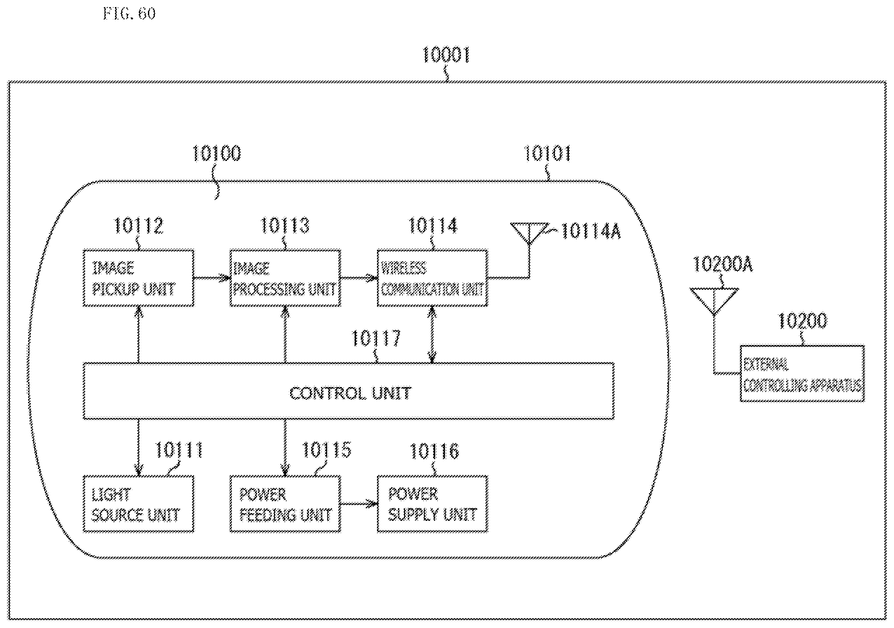

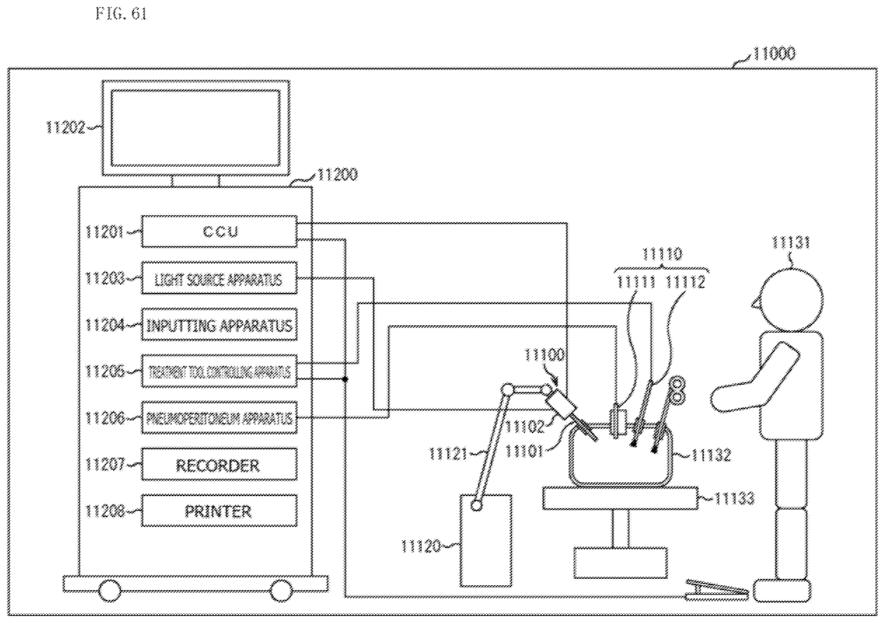

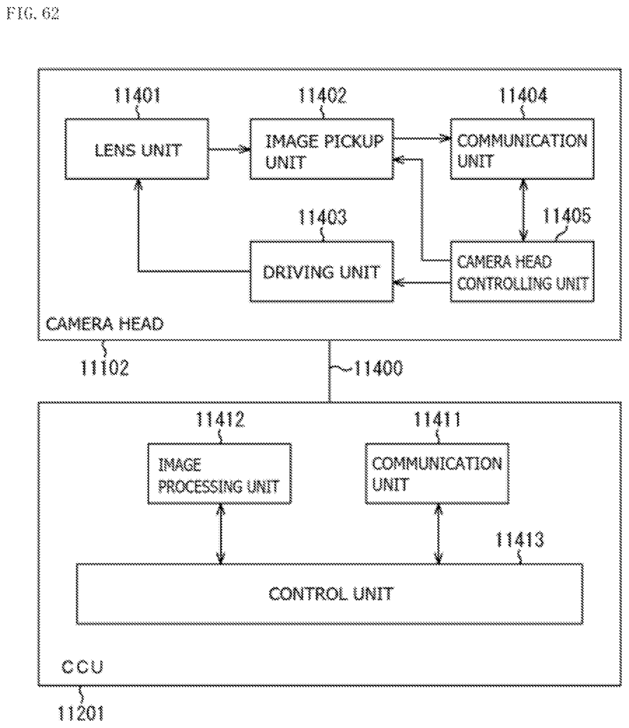

The above-described imaging devices 10 to 10I (referred to as imaging device 10 for short below) are each applicable, for example, to various types of imaging apparatuses (electronic apparatuses) such as a camera. FIG. 59 illustrates a schematic configuration of an electronic apparatus 3 (camera) as an example thereof. This electronic apparatus 3 is, for example, a camera that is able to shoot a still image or a moving image. The electronic apparatus 3 includes the imaging device 10, an optical system (optical lens) 310, a shutter device 311, a driver 313 that drives the imaging device 10 and the shutter device 311, and a signal processor 312.

The optical system 310 guides image light (incident light) from a subject to the imaging device 10. This optical system 310 may include a plurality of optical lenses. The shutter device 311 controls a period in which the imaging device 10 is irradiated with the light and a period in which light is blocked. The driver 313 controls a transfer operation of the imaging device 10 and a shutter operation of the shutter device 311. The signal processor 312 performs various kinds of signal processing on a signal outputted from the imaging device 10. An image signal Lout subjected to the signal processing is stored in a storage medium such as a memory or outputted to a monitor or the like.

### EXAMPLE OF APPLICATION TO IN-VIVO INFORMATION ACQUISITION SYSTEM

Further, the technology (present technology) according to the present disclosure is applicable to a variety of products. For example, the technology according to the present disclosure may be applied to an endoscopic surgery system.

FIG. 60 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below

The capsule type endoscope 10100 includes a housing 10101 of the capsule type, in Which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element, in the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 60, in order to avoid complicated illustration, an arrow mark indicative of a supply destination of electric power from the power supply unit 10116 and so forth are omitted. However, electric power stored in the power supply unit 10116 is supplied to and can he used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. in the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The above has described the example of the in-vivo information acquisition system to which the technology according to the present disclosure may be applied. The technology according to the present disclosure may be applied, for example, to the image pickup unit 10112 among the above-described components. This increases the detection accuracy.

### EXAMPLE OF APPLICATION TO ENDOSCOPIC SURGERY SYSTEM

The technology (present technology) according to the present disclosure is applicable to a variety of products. For example, the technology according to the present disclosure may be applied to an endoscopic surgery system.

FIG. 61 is a view depicting an example of a schematic configuration of an endoscopic surgery system to which the technology according to an embodiment of the present disclosure (present technology) can be applied.

In FIG. 61. a state is illustrated in which a surgeon (medical doctor) 11131 is using an endoscopic surgery system 11000 to perform surgery for a patient 11132 on a patient bed 11131 As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 1w a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 1121)6 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may he controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow hand in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 62 is a block diagram depicting an example of a functional configuration of the camera head 11102 and the CCU 11201 depicted in FIG. 61.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eve ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (Æ) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be applied to the image pickup unit 11402 among the above-described components. Applying the technology according to the present disclosure to the image pickup unit 11402 increases the detection accuracy.

it is to be noted that the endoscopic surgery system has been described here as an example, but the technology according to the present disclosure may be additionally applied, for example, to a microscopic surgery system or the like.

### EXAMPLE OF APPLICATION TO MOBILE BODY

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

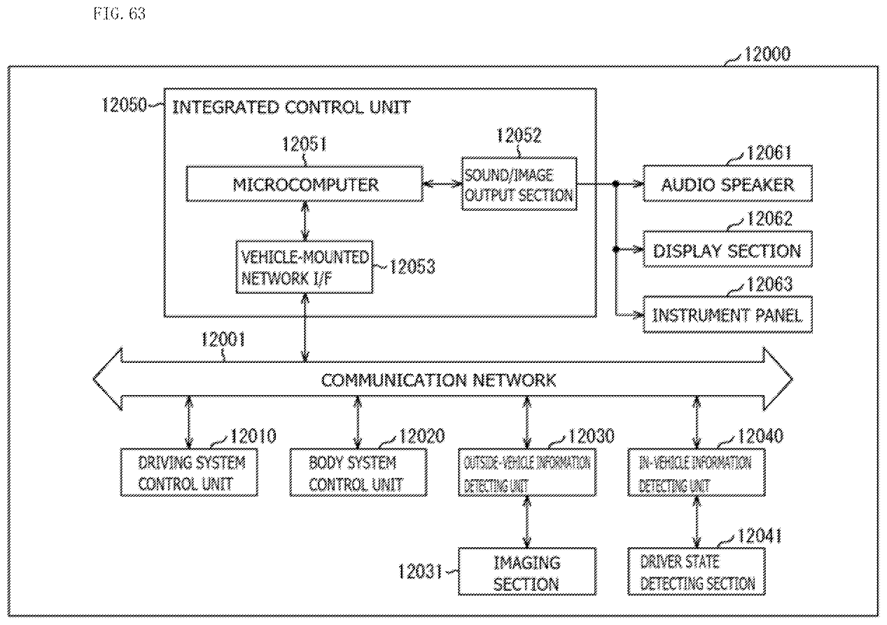

FIG. 63 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 63, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (1/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 63, an audio speaker 12061, a display section 12062, and an instrument panel 12063 are illustrated as the output device. The display section 12062 may, for example, include at least one of an on-board display and a head-up display.

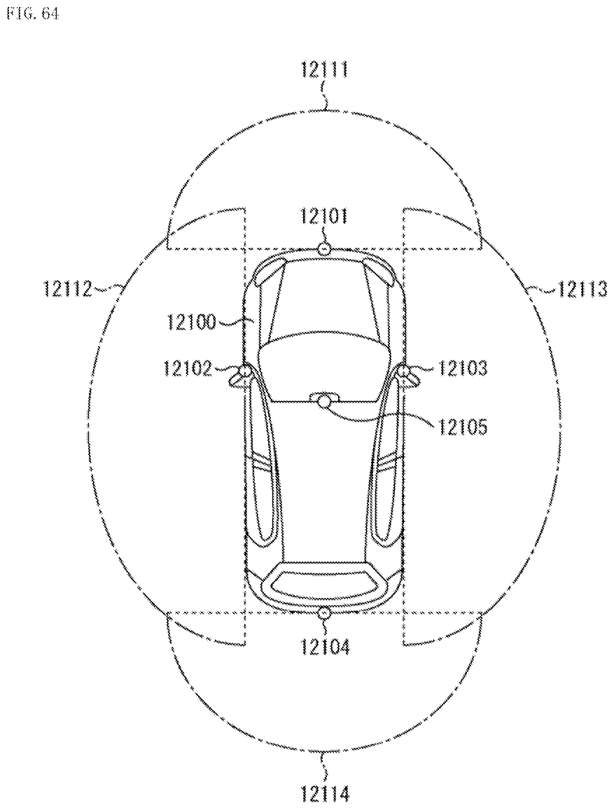

FIG. 64 is a diagram depicting an example of the installation position of the imaging section 12031.

In FIG. 64, the imaging section 12031 includes imaging sections 12101, 12102, 12103, 12104, and 12105,

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 64 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the vehicle control system to which the technology according to the present disclosure may be applied. The technology according to the present disclosure may be applied to the imaging section 12031 among the components described above. Applying the technology according to the present disclosure to the imaging section 12031 makes it possible to obtain a shot image that is easier to see. This makes it possible to decrease the fatigue of a driver.

The above has described the present disclosure with reference to the embodiments and the modification examples, but the present disclosure is not limited to the above-described embodiments or the like. The present disclosure may be modified in a variety of ways, For example, the respective layer configurations of the imaging devices described in the above-described embodiments are merely examples, Still another layer may be further included. In addition, the material and thickness of each layer are also merely examples. Those described above are not limitative.

In addition, in the above-described embodiments, the case has been described where the imaging device 10 is provided with the phase difference detection pixel PA along with the pixel P, but it is sufficient if the imaging device 10 is provided with the pixel P.

In addition, in the above-described embodiments, the case has been described where an imaging device is provided with the color microlenses 30R, 30G, and 30B or color filters 71R, 71G, and 71B for obtaining the received-light data of pieces of light within the red, green, and blue wavelength ranges, but the imaging device may be provided with a color microlens or color filter for obtaining the received-light data of light having another color. For example, color microlenses or color filters may be provided for obtaining the received-light data of pieces of light within the wavelength ranges such as cyan, magenta, and yellow. Alternatively, color microlenses or color fitters may be provided for obtaining the received-light data for white (transparent) and gray. For example, the received-light data for white is obtained by providing a color filter section including a transparent film. The received-light data for gray is obtained by providing a color filter section including a transparent resin to which black pigments are added such as carbon black and titanium black.

The effects described in the above-described embodiments and the like are merely examples. The effects may be any other effects or may further include any other effects.

It is to be noted that the present disclosure may have the following configurations. A solid-state imaging device according to the present disclosure having the following configurations and a method of manufacturing the solid-state imaging device have color filter sections in contact with each other between pixels adjacent in the first direction and the second direction, This makes it possible to suppress a decrease in sensitivity caused by pieces of light incident on the photoelectric converters without passing through the lens sections. The color filter sections are provided to the respective pixels. This makes it possible to increase the sensitivity.
(1)

A solid-state imaging device including:

a plurality of pixels each including a photoelectric converter, the plurality of pixels being disposed along a first direction and a second direction, the second direction intersecting the first direction; and

microlenses provided to the respective pixels on light incidence sides of the photoelectric converters, the microlenses including lens sections and an inorganic film, the lens sections each having a lens shape and being in contact with each other between the pixels adjacent in the first direction and the second direction, the inorganic film covering the lens sections, in which

the microlenses each include
first concave portions provided between the pixels adjacent in the first direction and the second direction, and
second concave portions provided between the pixels adjacent in a third direction, the second concave portions being disposed at positions closer to the photoelectric converter than the first concave portions, the third direction intersecting the first direction and the second direction.
(2)

The solid-state imaging device according to (1), in which the lens sections each include a color filter section having a light dispersing function, and

the microlenses each include a color microlens.
(3)

The solid-state imaging device according to (2), further including a light reflection film provided between the adjacent color filter sections.
(4)

The solid-state imaging device according to (2) or (3), in which

the color filter section includes a stopper film provided on a surface of the color filter section, and

the stopper film of the color filter section is in contact with the color filter section adjacent in the first direction or the second direction.
(5)

The solid-state imaging device according to any one of (2) to (4), in which the color filter sections adjacent in the third direction are provided by being linked.
(6)

The solid-state imaging device according to any one of (2) to (5), in which the color microlenses have radii of curvature different between respective colors.
(7)

The solid-state imaging device according to (1), in which

the lens sections include
first lens sections continuously arranged in the third direction, and
second lens sections provided to the pixels different from the pixels provided with the first lens sections, and

size of each of the first lens sections in the first direction and the second direction is greater than size of each of the pixels in the first direction and the second direction.
(8)

The solid-state imaging device according to any one of (1) to (7), further including a light-shielding film provided with an opening for each of the pixels.
(9)

The solid-state imaging device according to (8), in which the microlenses are each embedded in the opening of the light-shielding film.
(10)

The solid-state imaging device according to (8) or (9), in which the opening of the light-shielding film has a quadrangular planar shape.
(11)

The solid-state imaging device according to (8) or (9), in which the opening of the light-shielding film has a circular planar shape.
(12)

The solid-state imaging device according to any one of (1) to (11), including a plurality of the inorganic films.
(13)

The solid-state imaging device according to any one of (1) to (12), in which the plurality of pixels includes a red pixel, a green pixel, and a blue pixel.
(14)

The solid-state imaging device according to any one of (1) to (13), in which the microlens has a radius C1 of curvature in the first direction and the second direction and a radius C2 of curvature in the third direction for each of the pixels and the radius C1 of curvature and the radius C2 of curvature satisfy the following expression (1):

0.8×C1≤C2≤1.2×C1 (1)
(15)

The solid-state imaging device according to any one of to (14), further including a wiring layer provided between the photoelectric converters and the microlenses, the wiring layer including a plurality of wiring lines for driving the pixels.
(16)

The solid-state imaging device according to any one of (1) to (14), further including a wiring layer opposed to the microlenses with the photoelectric converters interposed between the wiring layer and the microlenses, the wiring layer including a plurality of wiring lines for driving the pixels.
(17)

The solid-state imaging device according to any one of (1) to (16), further including a phase difference detection pixel.
(18)

The solid-state imaging device according to any one of (1) to (17), further including a protective substrate opposed to the photoelectric converters with the microlenses interposed between the protective substrate and the photoelectric converters.
(19)

A method of manufacturing a solid-state imaging device, the method including:

forming a plurality of pixels each including a photoelectric converter, the plurality of pixels being disposed along a first direction and a second direction, the second direction intersecting the first direction;

forming first lens sections side by side in the respective pixels on light incidence sides of the photoelectric converters in the third direction, the first lens sections each having a lens shape;

forming second lens sections in the pixels different from the pixels in which the first lens sections are formed;

forming an inorganic film covering the first lens sections and the second lens sections; and

causing each of the first lens sections to have greater size in the first direction and the second direction than size of each of the pixels in the first direction and the second direction in forming the first lens sections.

The present application claims the priority on the basis of Japanese Patent Application No. 2018-94227 filed on May 16. 2018 with Japan Patent Office and Japanese Patent Application No. 2018-175743 filed on Sep. 20, 2018 with Japan Patent Office, the entire contents of which are incorporated in the present application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging device comprising:
a plurality of pixels each including a photoelectric converter, the plurality of pixels being disposed along a first direction and a second direction, the second direction intersecting the first direction; and
microlenses provided to the respective pixels on light incidence sides of the photoelectric converters, the microlenses including lens sections and an inorganic film, the lens sections each having a lens shape and being in contact with each other between the pixels adjacent in the first direction and the second direction, the inorganic film covering the lens sections, wherein
the microlenses each include
first concave portions provided between the pixels adjacent in the first direction and the second direction, and
second concave portions provided between the pixels adjacent in a third direction, the second concave portions being disposed at positions closer to the photoelectric converter than the first concave portions, the third direction intersecting the first direction and the second direction.

2. The solid-state imaging device according to claim 1, wherein
the lens sections each include a color filter section having a light dispersing function, and
the microlenses each include a color microlens.

3. The solid-state imaging device according to claim 2, further comprising a light reflection film provided between the adjacent color filter sections.

4. The solid-state imaging device according to claim 2, wherein
the color filter section includes a stopper film provided on a surface of the color filter section, and
the stopper film of the color filter section is in contact with the color filter section adjacent in the first direction or the second direction.

5. The solid-state imaging device according to claim 2, wherein the color filter sections adjacent in the third direction are provided by being linked.

6. The solid-state imaging device according to claim 2, wherein the color microlenses have radii of curvature different between respective colors.

7. The solid-state imaging device according to claim 1, wherein
the lens sections include
first lens sections continuously arranged in the third direction, and
second lens sections provided to the pixels different from the pixels provided with the first lens sections, and
size of each of the first lens sections in the first direction and the second direction is greater than size of each of the pixels in the first direction and the second direction.

8. The solid-state imaging device according to claim 1, further comprising a light-shielding film provided with an opening for each of the pixels.

9. The solid-state imaging device according to claim 8, wherein the microlenses are each embedded in the opening of the light-shielding film.

10. The solid-state imaging device according to claim 8, wherein the opening of the light-shielding film has a quadrangular planar shape.

11. The solid-state imaging device according to claim 8, wherein the opening of the light-shielding film has a circular planar shape.

12. The solid-state imaging device according to claim 1, comprising a plurality of the inorganic films.

13. The solid-state imaging device according to claim 1, wherein the plurality of pixels includes a red pixel, a green pixel, and a blue pixel.

14. The solid-state imaging device according to claim 1, wherein the microlens has a radius C1 of curvature in the first direction and the second direction and a radius C2 of curvature in the third direction for each of the pixels and the radius C1 of curvature and the radius C2 of curvature satisfy the following expression (1):
0.8×C1≤C2≤1.2×C1 (1)

15. The solid-state imaging device according to claim 1, further comprising a wiring layer provided between the photoelectric converters and the microlenses, the wiring layer including a plurality of wiring lines for driving the pixels.

16. The solid-state imaging device according to claim 1, further comprising a wiring layer opposed to the microlenses with the photoelectric converters interposed between the wiring layer and the microlenses, the wiring layer including a plurality of wiring lines for driving the pixels.

17. The solid-state imaging device according to claim 1, further comprising a phase difference detection pixel.

18. The solid-state imaging device according to claim 1, further comprising a protective substrate opposed to the photoelectric converters with the microlenses interposed between the protective substrate and the photoelectric converters.

19. A method of manufacturing a solid-state imaging device, the method comprising:
forming a plurality of pixels each including a photoelectric converter, the plurality of pixels being disposed along a first direction and a second direction, the second direction intersecting the first direction;
forming first lens sections side by side in the respective pixels on light incidence sides of the photoelectric converters in the third direction, the first lens sections each having a lens shape;
forming second lens sections in the pixels different from the pixels in which the first lens sections are formed;
forming an inorganic film covering the first lens sections and the second lens sections; and
causing each of the first lens sections to have greater size in the first direction and the second direction than size of each of the pixels in the first direction and the second direction in forming the first lens sections.
